(19) United States
(12) Patent Application Publication
(10) Pub. No.: US 2019/0157120 A1
(43) Pub. Date: May 23, 2019

(54) LASER DEVICE AND LASER ANNEAL DEVICE

(71) Applicant: Gigaphoton Inc., Tochigi (JP)

(72) Inventors: Satoshi TANAKA, Oyama-shi (JP); Osamu WAKABAYASHI, Oyama-shi (JP)

(73) Assignee: Gigaphoton Inc., Tochigi (JP)

(21) Appl. No.: 16/261,338

(22) Filed: Jan. 29, 2019

Related U.S. Application Data
(63) Continuation of application No. PCT/JP2016/076103, filed on Sep. 6, 2016.

(51) Int. Cl. H01L 21/67; B23K 26/352; B23K 26/0622

(52) U.S. Cl. CPC H01L 21/67115; H01L 27/1274; B23K 26/0622; B23K 26/352

(57) ABSTRACT

A laser device for laser annealing includes: (1) a laser oscillator configured to output pulse laser light; and (2) an optical pulse stretcher (OPS) device disposed on an optical path of the pulse laser light output from the laser oscillator and including at least one OPS configured to stretch a pulse time width of the pulse laser light incident on the OPS. A delay optical path length L(1) of a first OPS having the minimum delay optical path length L among OPSs is in a range of the following expression (A),

ΔT_{75%}×c≤L(1)≤ΔT_{25%}×c (A),

where ΔT_{a %} is a time full-width of a position at which light intensity represents a value of a % with respect to a peak value in an input waveform of the pulse laser light that is output from the laser oscillator and incident on the OPS device, and c is light speed.

### CROSS-REFERENCE TO RELATED APPLICATIONS

The present application is a continuation application of International Application No. PCT/JP2016/076103 filed on Sep. 6, 2016, The content of the application is incorporated herein by reference in its entirety.

### BACKGROUND

### 1. Technical Field

The present disclosure relates to a laser device and a laser anneal device.

### 2. Related Art

As a drive element for a flat panel display using a glass substrate, a thin film transistor (TFT) has been used. A TFT with a high driving force needs to be produced for achieving production of a high definition display. For a semiconductor thin film being a channel member of the TFT, polycrystalline silicon, indium gallium zinc oxide (IGZO), or the like has been used. Polycrystalline silicon and IGZO have higher carrier mobility and are more excellent in on-off characteristics of transistors than amorphous silicon.

The semiconductor thin film has also been expected to be applied to a three-dimensional integrated circuit (3D-IC) that leads to a higher functional device. The production of the 3D-IC is achieved by forming active elements such as a sensor, an amplifier circuit, or a CMOS circuit, on a top layer of an integrated circuit device. Hence, a technique for manufacturing a high-quality semiconductor thin film has been required.

Further, with diversification of information terminal devices, demands are increasing for a flexible display and a flexible computer which are small-sized, lightweight, and freely bendable and have small power consumption. There has thus been required establishment of a technique to form a high-quality semiconductor thin film on a plastic substrate such as polyethylene terephthalate (PET).

For forming the high-quality semiconductor thin film on the glass substrate, the integrated circuit, or the plastic substrate, it is necessary to crystallize the semiconductor thin film without causing thermal damage on these substrates. Process temperatures are required to be 400° C. for the glass substrate that is used as a display, 400° C. for the integrated circuit, and 200° C. or lower for the PET that is the plastic substrate.

Laser annealing has been used as a technique to crystallize the ground substrate of the semiconductor thin film without causing thermal damage on the substrate. In this method, pulse ultraviolet laser light which is absorbed by an upper layer of the semiconductor thin film is used to prevent damage on the substrate due to thermal diffusion.

When the semiconductor thin film is silicon, an XeF excimer laser with a wavelength of 351 nm, an XeCl excimer laser with a wavelength of 308 nm, a KrF excimer laser with a wavelength of 248 nm, or some other laser is used. These gas lasers with wavelengths in an ultraviolet region have characteristics of having low laser-light coherence and excellent energy uniformity on the laser light irradiation surface and being able to perform annealing with high pulse energy over a wide range, as compared to a solid-state laser.

### CITATION LIST

### Patent Literature

Patent Literature 1: International Publication No. WO 2014/156818

Patent Literature 2: Published Japanese Translations of PCT International Publication for Patent Application No. 2008-546188

Patent Literature 3: US Patent Application Publication No. 2012/0260847

### SUMMARY

A laser device for use in laser annealing according to one standpoint of the present disclosure includes: (1) a laser oscillator and (2) an optical pulse stretcher (OPS) device. (1) A laser oscillator is configured to output pulse laser light. (2) An optical pulse stretcher (OPS) device is disposed on an optical path of the pulse laser light output from the laser oscillator and including a first OPS. The first OPS is configured to stretch a pulse time width of the pulse laser light incident on the first OPS, by transmitting a part of the pulse laser light and causing the other part of the pulse laser light to circulate through a delay optical path and to be output. A delay optical path length L(1) as a length of the delay optical path of the first OPS is in a range of the following expression (A),

ΔT_{75%}×c≤L(1)≤ΔT_{25%}×c (A),

where ΔT_{a %} is a time full-width of a position at which light intensity represents a value of a % with respect to a peak value in an input waveform of the pulse laser light that is output from the laser oscillator and incident on the OPS device, and c is light speed.

### BRIEF DESCRIPTION OF THE DRAWINGS

Some embodiments of the present disclosure will be described with reference to accompanying drawings as simple examples.

FIG. 1 schematically illustrates a configuration of a laser anneal device according to a comparative example;

FIG. 2 schematically illustrates a configuration of the laser device of the comparative example;

FIG. 3 is an explanatory diagram of an action of an OPS;

FIG. 4 is an input waveform into an OPS device and an output waveform from the OPS device according to the comparative example;

FIG. 5 illustrates a configuration of a laser device according to a first embodiment;

FIG. 6 is an explanatory diagram of a pulse full-width;

FIG. 7 is pulse laser light in a case where a delay optical path length L(1) is ΔT_{75%}×c;

FIG. 8 is pulse laser light a case where a delay optical path length L(2) is ΔT_{50%}×c;

FIG. 9 is pulse laser light in a case where a delay optical path length L(3) is ΔT_{25%}×c;

FIG. 10 is an input waveform and an output waveform in Gaussian waveforms;

FIG. 11 is an input waveform and an output waveform in an XeF excimer laser;

FIG. 12 schematically illustrates a laser device including a three-stage OPS device according to a second embodiment;

FIG. 13 is an explanatory diagram of an action of the three-stage OPS device;

FIG. 14 is an output waveform of the three-stage OPS device;

FIG. 15A is an output waveform with L(1) being ΔT_{75%}×c;

FIG. 15B is an output waveform with L(1) being ΔT_{50%}×c;

FIG. 15C is an output waveform with L(1) being ΔT_{25%}×c;

FIG. 16A is an output waveform with L(1) being ΔT_{75%}×c in the XeF excimer laser;

FIG. 16B is an output waveform with L(1) being ΔT_{50%}×c in the XeF excimer laser;

FIG. 16C is an output waveform with L(1) being ΔT_{25%}×c in the XeF excimer laser;

FIG. 17 is an output waveform with L(1) being 3.5 m in the XeF excimer laser;

FIG. 18 is a graph representing relationship between a number of stages of the OPS device and a TIS pulse time width;

FIG. 19 is a configuration diagram of a plural-stage OPS device;

FIG. 20 schematically illustrates a laser device of a master oscillator power amplifier (MOPA) system according to a third embodiment;

FIG. 21 is an output waveform of one example of the third embodiment;

FIG. 22A is a graph representing relationship between a discharge timing delay time DSDT and pulse energy;

FIG. 22B is a graph representing relationship between the discharge timing delay time DSDT and a TIS pulse time width;

FIG. 23A is an output waveform in the case of the discharge timing delay time DSDT being 10 ns in the third embodiment;

FIG. 23B is an output waveform in the case of the discharge timing delay time DSDT being 15 ns in the third embodiment;

FIG. 23C is an output waveform in the case of the discharge timing delay time DSDT being 20 ns in the third embodiment;

FIG. 24 is a graph representing relationship between the discharge timing delay time DSDT and the TIS pulse time width, differently from FIG. 22B;

FIG. 25 is an output waveform in an example of a KrF excimer laser;

FIG. 26 is a graph representing relationship between the delay optical path length L(1) and a light intensity ratio Imr;

FIG. 27A is an output waveform in the case of changing a reflectance RB of a beam splitter;

FIG. 27B is a graph representing relationship between the reflectance RB and the light intensity, etc.;

FIG. 27C is a graph representing relationship bet-.ween the reflectance RB and the TIS pulse time width;

FIG. 28A is an output waveform in the case of setting the delay optical path length in conditions of L(1)=ΔT_{25%}×c, and L(k)=1.8×L(k−1);

FIG. 28B is an output waveform in the case of setting the delay optical path length in conditions of L(1)=ΔT_{25%}×c, and L(k)=2.0×L(k−1);

FIG. 28C is an output waveform in the case of setting the delay optical path length in conditions of L(1)=ΔT_{25%}×c, and L(k)=2.2×L(k−1);

FIG. 29A is an output waveform in the case of setting the delay optical path length in conditions of L(1)=ΔT_{50%}×c, and L(k)=1.8×L(k−1);

FIG. 29B is an output waveform in the case of setting the ay optical path length in conditions of L(1)=ΔT_{50%}×c, and L(k)=2.0×L(k−1);

FIG. 29C is an output waveform in the case of setting the delay optical path length in conditions of L(1)=ΔT_{50%}×c, and L(k)=2.2×L(k−1);

FIG. 30A is an output waveform in the case of setting the delay optical path length in conditions of L(1)=ΔT_{75%}×c, and L(k)=1.8×L(k−1);

FIG. 30B is an output waveform in the case of setting the ay optical path length in conditions of L(1)=ΔT_{75%}×c, and L(k)=2.0×L(k−1);

FIG. 30C is an output waveform in the case of setting the delay optical path length in conditions of L(1)=ΔT_{75%}×c, and L(k)=2.2×L(k−1);

FIG. 31 is a graph representing relationship between the number of stages of the OPS device and the TIS pulse time width in the output waveform of FIGS. 29A to 30C; and

FIG. 32 is an output waveform in the KrF excimer laser of the MOPA system.

### EMBODIMENTS

<Contents>
1. Summary
2. Laser anneal device according to comparative example

2.1 Configuration of laser anneal device

2.2 Operation of laser anneal device

2.3 Detail of laser device

2.3.1 Configuration of laser device having optical pulse stretcher (OPS)

2.3.2 Detail of OPS

2.4 Problem
3. Laser device of first embodiment and laser anneal device using the same

3.1 Configuration

3.2 Action of OPS device

3.3 Effect of OPS device

3.4 Example of XeF excimer laser

3.5 Others
4. Laser device of second embodiment and laser anneal device using the same

4.1 Configuration

4.2 Action of OPS device

4.3 Effect

4.4 Example 1 of XeF excimer laser

4.5 Example 2 of XeF excimer laser

4.6 Modified Example (OPS device configured by first to n-th OPSs)

4.7 Others
5. Laser device of third embodiment and laser anneal device using the same

5.1 Configuration

5.2 Operation

5.3 Example of XeF excimer laser, MOPA system, and one-stage OPS device

5.3.1 Configuration

5.3.2 Action

5.3.3 Effect

5.4 Relationship between discharge timing delay time DSDT and pulse energy/TIS pulse time width ΔT_{TIS}

5.5 Suppressing fluctuation of pulse time width by combination of MOPA system and OPS device

5.5.1 Output waveform in combination of MOPA system and OPS device

5.5.2 Effect to suppress fluctuation of TIS pulse time width ΔT_{TIS}

5.5.3 Others
6. Preferable ranges of various conditions

6.1 More preferable range of delay optical path length L(1)

6.2 Preferable range of reflectance RB of beam splitter

6.3 Preferable range of delay optical path length L(1)

6.4 Others

Hereinafter, embodiments of the present disclosure will be described in detail with reference to the drawings. The embodiments described below are to show some examples of the present disclosure and not to limit the contents of the present disclosure. Not all of configurations and operations described in the embodiments are necessarily essential as the configurations and operations of the present disclosure. The same constituents are denoted by the same reference numerals to omit repeated description.

### 1. Summary

The present disclosure relates to a laser device for laser annealing in use for a laser anneal device that anneals a semiconductor thin film by performing irradiation with pulse laser light so as to crystallize the semiconductor thin film.

### 2. Laser Anneal Device According to Comparative Example

2.1 Configuration of Laser Anneal Device

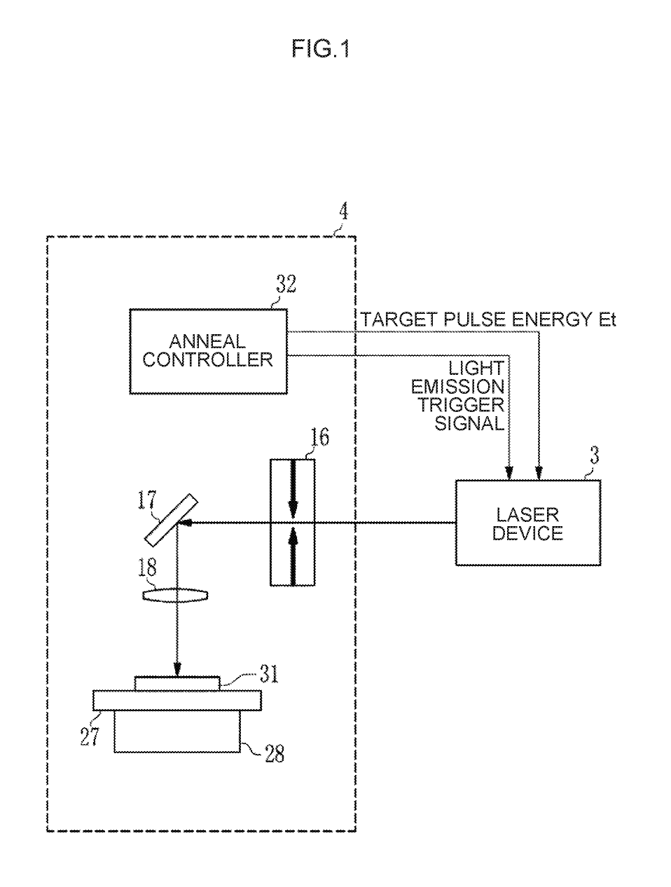

FIG. 1 schematically illustrates a configuration of a laser anneal device according to a comparative example. The laser anneal device includes a laser device 3 and an anneal device 4. The laser device 3 and the anneal device 4 are connected to each other with an optical path pipe (not illustrated).

The laser device 3 is a laser device that outputs pulse laser light by pulse oscillation and is an excimer pulse laser device using ArF, KrF, XeCl, or XeF as a laser medium. In the case of an ArF excimer pulse laser device, a center wavelength of pulse laser light is about 193.4 nm. In the case of a KrF excimer pulse laser device, a center wavelength of pulse laser light is about 248.4 nm. In the case of an XeCl excimer pulse laser device, a center wavelength of pulse laser light is about 308 mm In the case of an XeF excimer pulse laser device, a center wavelength of pulse laser light is about 351 nm.

The anneal device 4 includes a slit 16, a high reflective mirror 17, a transfer optical system 18, a table 27, an XYZ stage 28, and an anneal controller 32.

The slit 16 is disposed so as to allow passage of pulse laser light in a region of its beam cross section which has a uniform light intensity distribution. The high reflective mirror 17 reflects pulse laser light input from the laser device 3, toward the transfer optical system 18. The transfer optical system 18 is an optical system that forms a transferred image of the slit 16 on the surface of an irradiated object 31. The transfer optical system 18 may be configured by one convex lens or may be an optical system including one or a plurality of convex lenses and one or a plurality of concave lenses.

A table 27 supports the irradiated object 31. The irradiated object 31 is an object to be irradiated with the pulse laser light and annealed. In the present example, the irradiated object 31 is an intermediate product for manufacturing a TFT substrate. An XYZ stage 28 supports a table 27. The XYZ stage 28 is movable in an X-axis direction, a Y-axis direction, and a Z-axis direction, and the position of the irradiated object 31 is adjustable by adjusting the position of the table 27. The XYZ stage 28 adjusts the position of the irradiated object 31 such that a transferred image is formed by the transfer optical system 18 on the surface of the irradiated object 31.

The anneal controller 32 transmits data of target pulse energy Et and a light emission trigger signal to the laser device 3, to control pulse energy and irradiation timing of pulse laser light, with which the irradiated object 31 is irradiated. In addition, the anneal controller 32 controls the XYZ stage 28.

The irradiated object 31 includes, for example, a glass substrate and an amorphous silicon film formed on the glass substrate. The amorphous silicon film is a thin film of amorphous silicon (a-Si) and is an object to be annealed.

2.2 Operation of Laser Anneal Device

In the case of performing the annealing, first, the irradiated object 31 is set on the XYZ stage 28. The anneal controller 32 causes the XYZ stage 28 to adjust the position of the irradiated object 31 in the X-axis direction and the Y-axis direction, thereby moving the irradiated object 31 to a position at which an image is formed by the transfer optical system 18.

Next, the anneal controller 32 transmits the data of the target pulse energy Et to the laser device 3. The anneal controller 32 transmits light emission trigger signals in number corresponding to a pre-sot pulse number at a predetermined repetition frequency.

The laser device 3 outputs pulse laser light based on the received data of the target pulse energy Et and the light emission trigger signal. The pulse laser light output by the laser device 3 is input into the anneal device 4. In the anneal device 4, the pulse laser light is transmitted through the slit 16, reflected by the high reflective mirror 17, and incident on the transfer optical system 18.

The transfer optical system 18 transfers the transferred image of the slit 16 onto the surface of the irradiated object 31. Hence, the amorphous silicon film on the surface of the irradiated object 31 is irradiated with the pulse laser light. When the amorphous silicon film is irradiated with the pulse laser light, the temperature of the amorphous silicon film increases to become equal to or higher than its melting point, and the amorphous silicon film melts. After melting, the amorphous silicon film is crystallized in the process of being re-solidified. As a result, the amorphous silicon film is reformed into a polycrystalline silicon film.

2.3 Detail of Laser Device

2.3.1 Configuration of Laser Device Having Optical Pulse Stretcher (OPS)

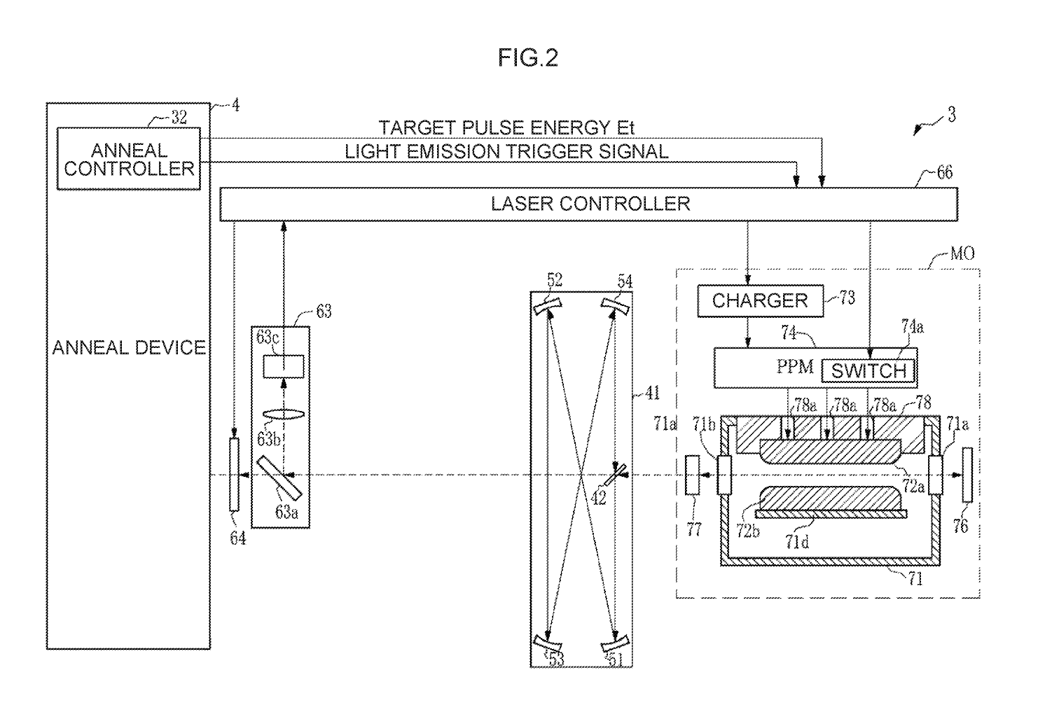

FIG. 2 illustrates a specific configuration of the laser device 3. The laser device 3 includes a master oscillator MO being the laser oscillator, an OPS 41, a pulse energy measuring unit 63, a shutter 64, and a laser controller 66.

The master oscillator MO includes a laser chamber 71, a pair of electrodes 72a, 72b, a charger 73, and a pulse power module (PPM) 74. The master oscillator MO further includes a high reflective mirror 76 and an output coupling mirror 77. FIG. 2 illustrates an internal configuration of the laser chamber 71 as seen from a direction substantially vertical to a traveling direction of the laser light and a discharging direction.

The laser chamber 71 is a chamber in which the laser medium described above is sealed. The pair of electrodes 72a, 72b are arranged in the laser chamber 71 as electrodes for exciting the laser medium by discharging. An opening is formed in the laser chamber 71, and an electric insulation part 78 closes this opening. The electric insulation part 78 supports the electrode 72a, and a return plate 71d supports the electrode 72b. This return plate 71d is connected to the internal surface of the laser chamber 71 by wiring (not illustrated). A conductive part 78a is embedded in the electric insulation part 78. The conductive part 78a applies a high voltage supplied from the pulse power module 74, to the electrode 72a.

The charger 73 is a direct-current power source device that charges a charging capacitor (not illustrated) in the pulse power module 74 with a predetermined voltage. The pulse power module 74 includes a switch 74a controlled by the laser controller 66, for example. When the switch 74a is turned on from off, the pulse power module 74 generates a pulsed high voltage from electric energy held in the charger 73 and this high voltage is applied to the pair of electrodes 72a, 72b.

When the high voltage is applied to the pair of electrodes 72a, 72b, insulation breakdown occurs between the pair of electrodes 72a, 72b, and discharge is caused. The laser medium in the laser chamber 71 is excited by energy of the discharge and shifts to a high energy level. When the excited laser medium then shifts to a low energy level, light corresponding to the difference between those energy levels is emitted.

Windows 71a, 71b are provided at both ends of the laser chamber 71. The light generated in the laser chamber 71 is emitted to the outside of the laser chamber 71 via the windows 71a, 71b.

The high reflective mirror 76 reflects the light emitted from the window 71a of the laser chamber 71 at a high reflectance and returns the light to the laser chamber 71. The output coupling mirror 77 transmits and outputs a part of the light output from the window 71b of the laser chamber 71, and reflects and returns the other part of the light into the laser chamber 71.

Therefore, the high reflective mirror 76 and the output coupling mirror 77 constitute an optical resonator. The light emitted from the laser chamber 71 reciprocates between the high reflective mirror 76 and the output coupling mirror 77 and is amplified each time the light passes through a laser gain space between the electrode 72a and the electrode 72b. A part of the amplified light is output as pulse laser light via the output coupling mirror 77.

The OPS 41 constitutes the OPS device. The OPS device transmits a part of the pulse laser light output from the master oscillator MO, and causes the other part of the pulse laser light to circulate through a delay optical path and then be output, thereby stretching a pulse time width of the pulse laser light. The OPS device of the present example is configured by one OPS 41. The OPS 41 is disposed on a subsequent stage to the master oscillator MO. The OPS 41 includes a beam splitter 42 and first to fourth concave mirrors 51 to 54.

The beam splitter 42 is a partial reflective mirror and is formed by, for example, coating a film on a CaF₂ substrate, the film partially reflecting pulse laser light, the substrate highly transmitting pulse laser light. The beam splitter 42 is disposed on an optical path of pulse laser light output from the master oscillator MO. The beam splitter 42 transmits a part of the incident pulse laser light and reflects the other part thereof.

The first to fourth concave mirrors 51 to 54 constitute a delay optical path configured to stretch the pulse time width of the pulse laser light. The first to fourth concave mirrors 51 to 54 each have a mirror surface with the same curvature radius r. The first and second concave mirrors 51, 52 are arranged such that light reflected by the beam splitter 42 is reflected by the first concave mirror 51 and incident on the second concave mirror 52. The third and fourth concave mirrors 53, 54 are arranged such that light reflected by the second concave mirror 52 is reflected by the third concave mirror 53 and further reflected by the fourth concave mirror 54 and is then incident on the beam splitter 42 again.

The distance between the beam splitter 42 and the first concave mirror 51 and the distance between the fourth concave mirror 54 and the beam splitter 42 are each a half of the curvature radius r, namely, r/2. The distance between the first concave mirror 51 and the second concave mirror 52, the distance between the second concave mirror 52 and the third concave mirror 53, and the distance between the third concave mirror 53 and the fourth concave mirror 54 are the same as the curvature radius r.

The first to fourth concave mirrors 51 to 54 each have the same focal distance F. The focal distance F is a half of the curvature radius r, namely, F=r/2. Therefore, a delay optical path length L is a length of the delay optical path configured by the first to fourth concave mirrors 51 to 54 and is eight times as large as the focal distance F. That is, the OPS 41 has the relationship of L=8F.

The time difference corresponding to the delay optical path length L formed by the first to fourth concave mirrors 51 to 54 is generated between the pulse laser light output from the OPS 41 without circulating through the delay optical path and the pulse laser light output after circulating through the delay optical path. Thereby, the OPS 41 stretches the pulse time width of the pulse laser light.

The pulse energy measuring unit 63 is disposed on the optical path of the pulse laser light having passed through the OPS 41. The pulse energy measuring unit 63 includes, for example, a beam splitter 63a, a light collecting optical system 63b, and an optical sensor 63c.

The beam splitter 63a transmits the pulse laser light having passed through the OPS 41, with a high transmittance toward the shutter 64 and reflects a part of the pulse laser light toward the light collecting optical system 63b. The light collecting optical system 63b collects the light reflected by the beam splitter 63a on the light receiving surface of the optical sensor 63c. The optical sensor 63c detects pulse energy of the pulse laser light collected by the light receiving surface and outputs data of the detected pulse energy to the laser controller 66.

The laser controller 66 transmits and receives various signals to and from the anneal controller 32. For example, the laser controller 66 receives from the anneal controller 32 a light emission trigger signal, data of the target pulse energy Et, and the like. The laser controller 66 transmits a setting signal for a charged voltage to the charger 73 and transmits a command signal for switching on or off to the pulse power module 74.

The laser controller 66 receives the pulse energy data from the pulse energy measuring unit 63. With reference to the pulse energy data, the laser controller 66 controls the charged voltage of the charger 73. By controlling the charged voltage of the charger 73, the pulse energy of the pulse laser light is controlled. Further, the laser controller 66 corrects the timing of the light emission trigger signal in accordance with the set charged voltage value so that discharge is performed in a predetermined fixed time with respect to the light emission trigger signal.

The shutter 64 is disposed on the optical path of the pulse laser light transmitted through the beam splitter 63a of the pulse energy measuring unit 63. The laser controller 66 causes the shutter 64 to be closed after the start of laser oscillation until the difference between the pulse energy received from the pulse energy measuring unit 63 and the target pulse energy Et falls within an allowable range. The laser controller 66 causes the shutter 64 to be opened when the difference between the pulse energy received from the pulse energy measuring unit 63 and the target pulse energy Et falls within the allowable range. In synchronization with an opening/closing signal of the shutter 64, the laser controller 66 transmits, to the anneal controller 32, a signal indicating that the light emission trigger signal of the pulse laser light has become receivable.

2.3.2 Detail of OPS

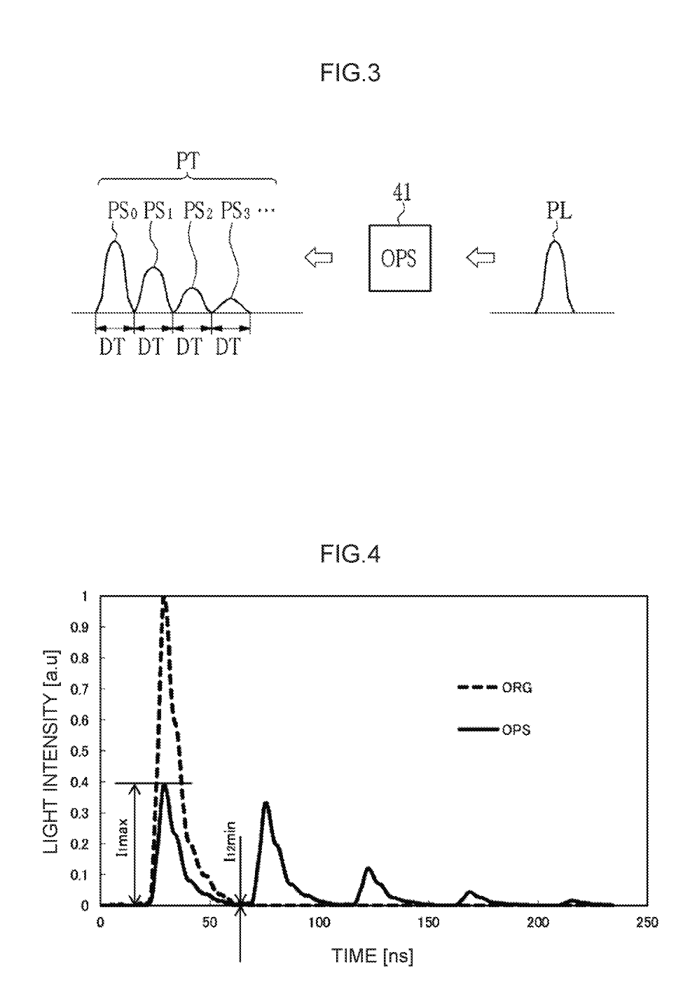

As illustrated in FIG. 3, pulse laser light PL output from the master oscillator MO is incident on the beam splitter 42 in the OPS 41. A part of the pulse laser light PL incident on the beam splitter 42 is transmitted through the beam splitter 42 and output from the OPS 41 as zero-circulation light PS₀ that has not circulated through the delay optical path.

Reflected light reflected by the beam splitter 42, of the pulse laser light PL having been incident on the beam splitter 42, enters the delay optical path and is reflected by the first concave mirror 51 and the second concave mirror 52. An optical image of the reflected light on the beam splitter 42 is formed by the first and second concave mirrors 51, 52 as a first transferred image of equal magnification. Then, a second transferred image of equal magnification is formed at the position of the beam splitter 42 by the third concave mirror 53 and the fourth concave mirror 54.

A part of the light incident on the beam splitter 42 as the second transferred image is reflected by the beam splitter 42 and output from the OPS 41 as one-circulation light PS₁ having circulated through the delay optical path once. This one-circulation light PS₁ is output with a delay by a delay time DT from the zero-circulation light PS₀. This DT is expressed by: DT=L/c, where c is light speed.

Transmitted light transmitted through the beam splitter 42, of the light having been incident on the beam splitter 42 as the second transferred image, enters the delay optical path once again and is reflected by the first to fourth concave mirrors 51 to 54 to he incident on the beam splitter 42 again. The reflected light reflected by the beam splitter 42 is output from the OPS 41 as two-circulation light PS₂ having circulated through the delay optical path twice. This two-circulation light PS₂ is output with a delay by the delay time DT from the one-circulation light PS₁.

Thereafter, by the light repeatedly circulating through the delay optical path, the pulse light is output in order of three-circulation light PS₃, four-circulation light PS₄, . . . from the OPS 41. Further, the pulse light output from the OPS 41 attenuates each time the beam splitter 42 repeats transmission or reflection, so that the light intensity decreases with increase in number of circulation times of the delay optical path.

As illustrated in FIG. 3, as a result of incidence of the pulse laser light PL on the OPS 41, the pulse laser light PL is divided into a plurality of pulse light beams PS₀, PS₁, PS₂, . . . having time differences and then output. Pulse laser light PT output from the OPS 41 is obtained by synthesizing a plurality of circulation light beams PSᵢ (i=0, 1, 2, . . . ) divided from the pulse laser light PL by the OPS 41, where i represents the number of the circulation times of the delay optical path.

As apparent from the above description, the delay optical path length L of the OPS 41 is the difference between one pulse light beam (circulation light PS) divided and sequentially output from the OPS 41 and one pulse light beam (circulation light PS) output subsequently in a case where the pulse laser light is incident on the OPS 41.

FIG. 4 is a graph representing an input waveform of the pulse laser light PL that is output from the master oscillator MO and incident on the OPS 41, and an output waveform of the pulse laser light PL after the pulse time width has been stretched by the OPS 41. A vertical axis of the graph represents light intensity [au.] and a horizontal axis thereof represents time The light intensity [a.u.] is a value normalized with a peak value of an original waveform taken as 1. In FIG. 4, a graph indicated by a broken line is an input waveform ORG of the pulse laser light PL and is the original waveform before the stretching. The input waveform ORG is formed by plotting data of the original waveform measured with actual equipment. In contrast, a graph indicated by a solid line is an output waveform OPS of the pulse laser light formed by performing simulation based on the input waveform ORG. In the simulation of the output waveform OPS, conditions of the OPS 41 according to the comparative example are: the delay optical path length L is 14 m; and the reflectance R of the beam splitter 42 is 60%.

While the TIS (time-integral-squared) pulse time width ΔT_{TIS} of the input waveform ORG is about 19.0 ns, the TIS pulse time width ΔT_{TIS} of the output waveform OPS after the stretching has been stretched to about 55.0 ns.

In this case, the TB pulse time width ΔT_{TIS} is one index indicating a pulse time width ΔT and defined by an expression (1) below, where t is time, and 1(t) is light intensity at the time t. The use of the TIS pulse time width ΔT_{TIS} as the index of the pulse time width enables comparison between the input waveform MG having one peak and the output waveform OPS after the stretching which has a plurality of peaks.

$$\begin{matrix}[ Expression 1 ] & \\ Δ {T}_{TIS} = \frac{{[ \int I ( t ) dt ]}^{2}}{\int {I ( t )}^{2} dt} & ( 1 )\end{matrix}$$

2.4 Problem

The polycrystalline silicon film, generated by crystallizing the amorphous silicon film by laser annealing, consists of a large number of crystals, and a grain size of each crystal is preferably large. This is because, for example in the case of using a polycrystalline silicon film for a TFT channel, the larger the grain size of each crystal becomes, the smaller the number of interfaces between crystals in the channel becomes, and the less the diffusion of carriers occurs in the interfaces. That is, the larger the grain size of each crystal of the polycrystalline silicon film becomes, the higher the carrier mobility becomes, and the more the switching characteristics of the TFT improves.

As described above, an effective way to increase the grain size of crystal of the polycrystalline silicon is lengthening the time during which the melted state of the amorphous silicon is held in laser annealing so as to lengthen the time for solidifying the amorphous silicon. This requires stretching of the pulse time width of the pulse laser light with which the amorphous silicon is irradiated.

Further, as represented by the output waveform OPS of FIG. 4, when the pulse time width is stretched by the OPS 41, the output waveform of the pulse laser light after the stretching becomes a waveform formed by synthesizing a plurality of circulation light beams PS, so that a plurality of peaks of light intensity may often occur. It has been verified by testing that in the above case, the effect of making the grain size of the crystal large is higher when a decrease in light intensity from the first peak to the second peak is smaller in the output waveform, in addition to simple stretching of the pulse time width of the output waveform. This is considered because, when the decrease in light intensity is large in a valley between the first peak and the second peak in the output waveform, the amorphous silicon in the melted state is cooled by heat dissipation in the valley section and may be re-solidified during irradiation with the pulse laser light.

Further, a third peak and subsequent peaks may occur in the output waveform, but the attenuation of the light intensity is weaker at the third and subsequent peaks than at the first and second peaks, so that the light intensity decreases in a relatively small degree after each peak. Thus, it is important for obtaining an effect to prevent the re-solidification and increase the crystal grain size to suppress the decrease in light intensity in the valley between the first and second peaks as much as possible.

in the output waveform, the light intensity ratio Imr is defined by the following expression (2) as an index indicating the degree of the decrease in light intensity which causes re-solidification:

Imr=I₁₂min/I₁max×100 (2).

As illustrated in FIG. 4, a light intensity I₁max is the maximum value being a peak value of the optical intensity at the first peak, and a light intensity I₁₂min is the minimum value of the light intensity in the valley between the first and second peaks, in the output waveform OPS. That is, the light intensity ratio Imr represents a radio of the light intensity in the valley between the first and second peaks with respect to the light intensity at the first peak.

In the output waveform OPS illustrated in FIG. 4, an interval between the first and second peaks is wide and the light intensity I₁₂ min in the valley is almost zero. Hence, the light intensity ratio Imr of the output waveform OPS is 0%.

As described above, even if the pulse time width of the pulse laser light is stretched in laser annealing, when the light intensity ratio Imr is small, the amorphous silicon in the melted state is re-solidified and the grain size of crystal of the polycrystalline silicon is hardly increased.

### 3. Laser Device of First Embodiment and Laser Anneal Device Using the Same

3.1 Configuration

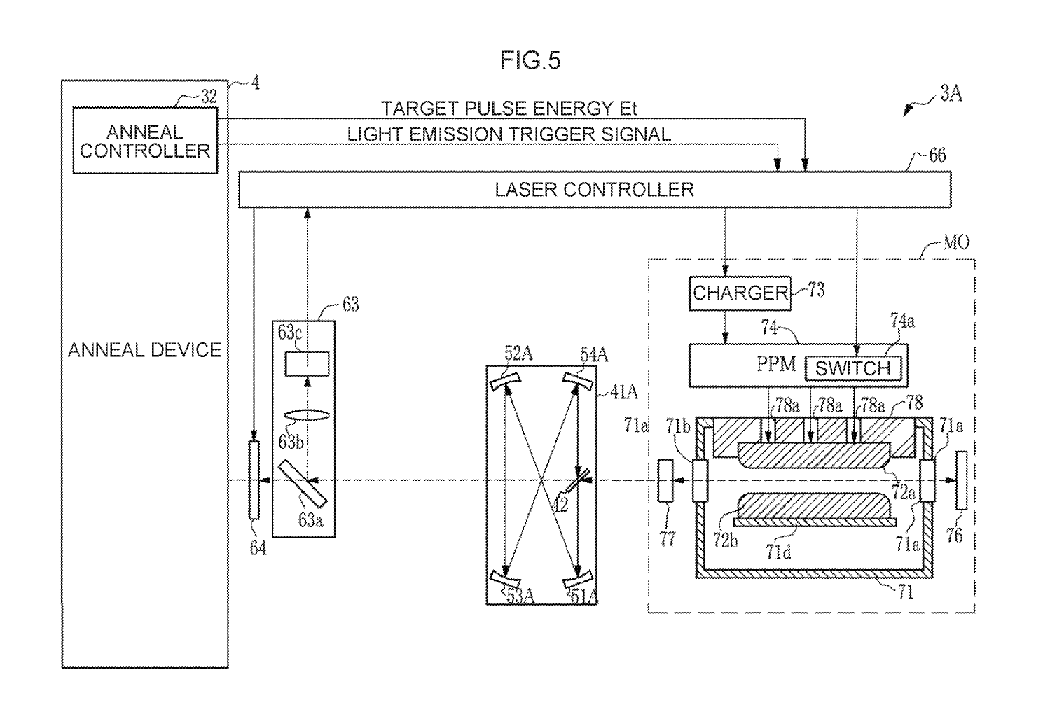

FIG. 5 schematically illustrates a configuration of a laser anneal device according to a first embodiment. The laser anneal device of the first embodiment includes a laser device 3A in place of the laser device 3 in the laser anneal device of the comparative example described with reference to FIG. 1. The laser device 3A of the first embodiment is different from the laser device 3 according to the comparative example in that an OPS 41.A is provided in place of the OPS 41. The OPS 41A corresponds to the first OPS in the present disclosure. In the laser device 3A of the first embodiment, the OPS device is configured by one OPS 41A. Since the other constituents are similar to those of the laser device 3, the same constituents are denoted by the same numerals, and the difference will be mainly described below.

The OPS 41A is configured by the beam splitter 42 and the first to fourth concave mirrors 51A to 54A as is the OPS 41, but has the delay optical path length L shorter than that of the OPS 41. Specifically, the focal distance F of the first to fourth concave mirrors 51A to 54A in the OPS 41A is respectively shorter than the focal distance F of the first to fourth concave mirrors 51 to 54 in the OPS 41 according to the comparative example. As described above, when the delay optical path is configured by the four concave mirrors being the first to fourth concave mirrors 51A to 54A, the delay optical path length L is 8F. In the OPS 41A, the focal distance F of the first to fourth concave mirrors 51A to 54A is shorter than that of the OPS 41 and the arrangement interval between each of the first to fourth concave mirrors 51A to 54A is an interval corresponding to the focal distance F, so that the OPS 41A has the delay optical path length L shorter than that of the OPS 41.

The OPS 41A corresponds to the first OPS. Assuming that the delay optical path length L of the OPS 41A is L(1), the delay optical path length L(1) is set in a range shown in the following expression (3):

ΔT_{75%}×c≤L(1)≤ΔT_{25%}×c (3),

where ΔT_{a %} is a pulse time width of pulse laser light that is output from the master oscillator MO (corresponding to the laser oscillator) and incident on the OPS 41A (corresponding to the OPS device including the first OPS). ΔT_{a %} is one of indexes indicating the pulse time width of the pulse laser light as is the TIS pulse time width ΔT_{TIS}, but is defined as follows differently from the TIS pulse time width ΔT_{TIS}.

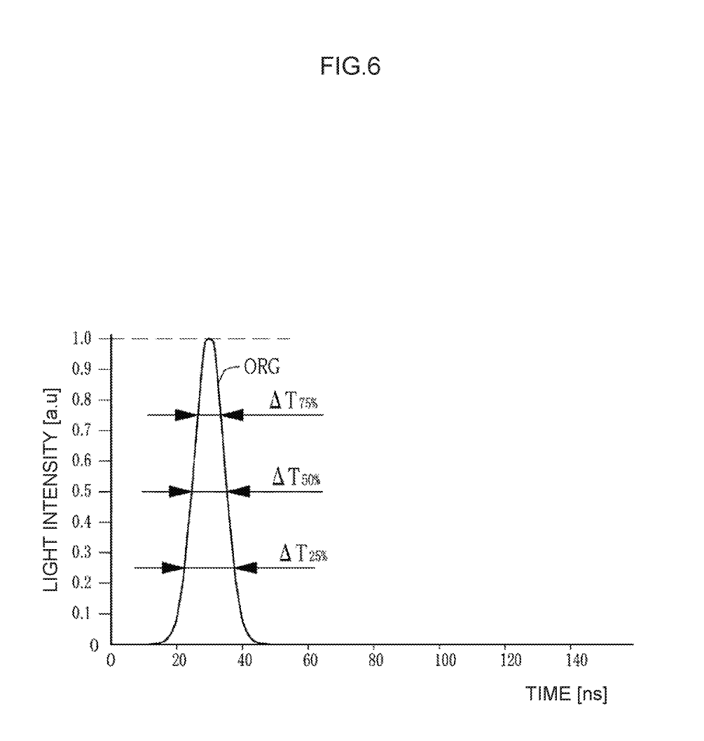

As illustrated in FIG. 4, the input waveform ORG of the pulse laser light which is output from the master oscillator MO and incident on the OPS 41A, has one peak. As illustrated in FIG. 6, in the input waveform ORG, ΔT_{a %} is a time full-width of a position at which the light intensity shows a value of a % with respect to a peak value. In the expression (3), c is light speed. Especially, ΔT_{50%} is a time full-width of a position at which the light intensity shows a value of 50% with respect to the peak value in the input waveform ORG, and is a so-called full width at half maximum (FWHM). Hereinafter, ΔT_{a %} is referred to as a pulse full-width to be distinguished from the TIS pulse time width ΔT_{TIS}.

The input waveform ORG illustrated in FIG. 6 is calculated assuming that a pulse waveform output from the master oscillator MO is a Gaussian waveform. Specific values of the pulse time width of the input waveform ORG in the present example are exemplifies as follows. The pulse full-width ΔT_{50%} being a FWHM is 10.6 ns. The pulse full-widths ΔT_{75%} and ΔT_{25%} are 6.8 ns and 15 ns, respectively. Further, the TIS pulse time width ΔT_{TIS} is 16 ns.

3.2 Action of OPS Device

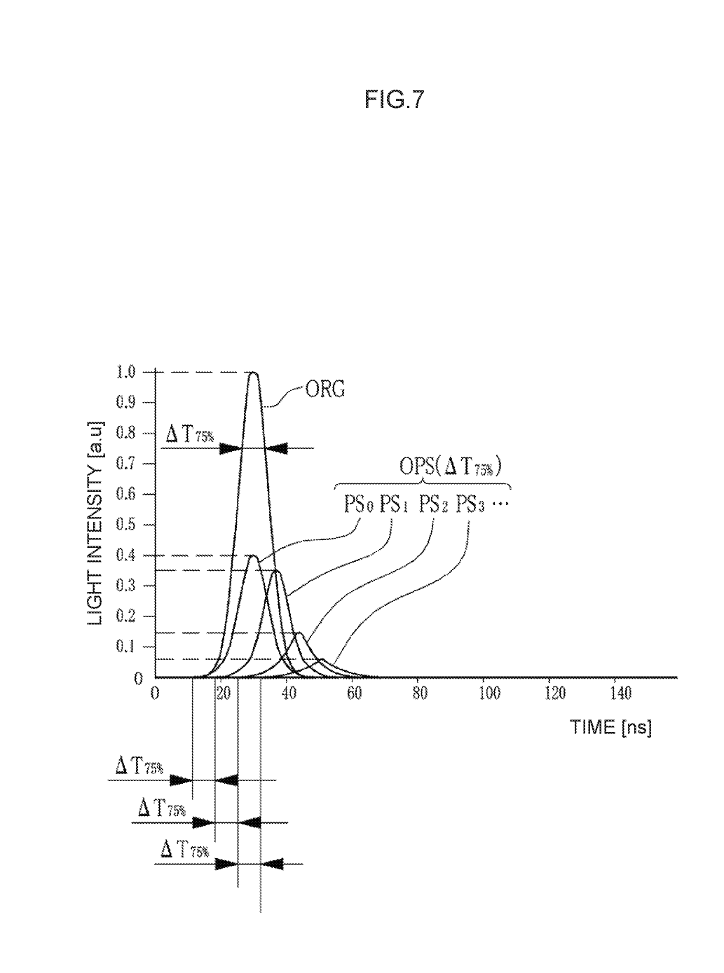

A graph illustrated in FIG. 7 represents the output waveform OPS after the stretching in a case where the delay optical path length L(1) of the OPS 41A is ΔT_{75%}×c. As illustrated in FIG. 7, when the delay optical path length L(1) is ΔT_{75%}×c, the time difference between each circulation light PS, output from the OPS 41A, is the pulse full-width ΔT_{75%}. The calculation is performed assuming that the light speed c is 0.3 m/ns. When the pulse full-width ΔT_{75%} is 6.8 ns, the delay optical path length L(1) is 2.04 m.

The reflectance of the beam splitter 42 is set at about 60%. Thus, since the zero-circulation light PS₀ is transmitted through the beam splitter 42 and output, when the peak value of the original waveform is assumed to be 1, the peak value of the light intensity attenuates to 0.4 (about 40%). The one-circulation light PS₁ is reflected once by the beam splitter 42, enters the delay optical path, and is reflected once again to be output, so that the peak value of the light intensity attenuates to: 0.6×0.6=0.36 (about 36%). Similarly, the peak value of the light intensity of the two-circulation light PS₂ attenuates to: 0.6×0.4×0.6=0.144 (about 14.4%), and the peak value of the light intensity of the three-circulation light PS₃ attenuates to: 0.6×0.4×0.4×0.6=0.0576 (about 5.76%).

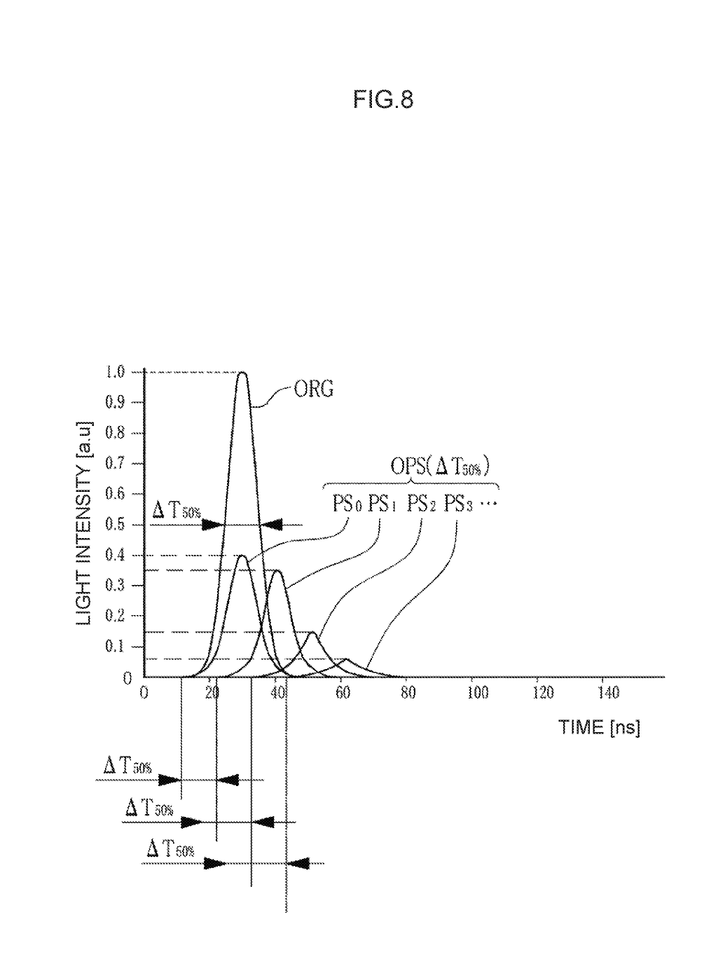

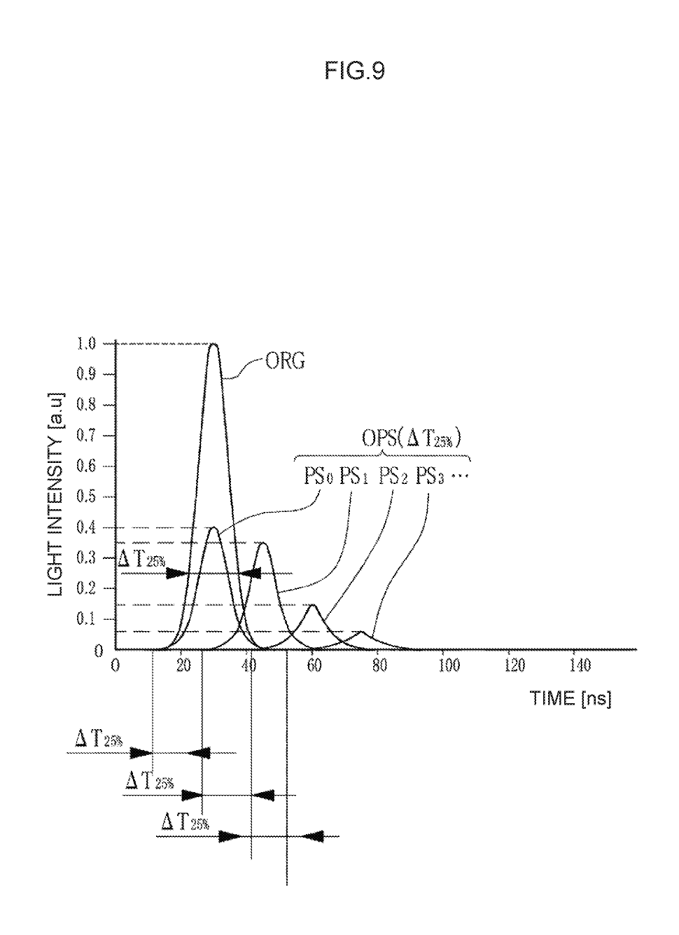

A graph illustrated in FIG. 8 represents the output waveform OPS after the stretching in a case where the delay optical path length L(1) of the OPS 41A is ΔT_{50%}×c. A graph illustrated in FIG. 9 represents the output waveform OPS after the stretching in a case where the delay optical path length L(1) of the OPS 41A is ΔT_{25%}×c. As illustrated in FIG. 8, when the delay optical path length L(1) is ΔT_{50%}×c, the time difference between each circulation light PS, output from the OPS 41A, is the pulse full-width ΔT_{50%.} As illustrated in FIG. 9, when the delay optical path length L(1) is ΔT_{25%}×c, the time difference between each circulation light PS, output from the OPS 41A, is the pulse full-width ΔT₂₅%. The light intensity of each circulation light PS is similar to that in the graph of FIG. 7.

When the pulse full-width ΔT_{50%} is 10.6 ns, the delay optical path length L(1) is calculated by: L(1)=ΔT_{50%}×c=10.6 ns×0.3 m/ns=3.18 m. When the pulse full-width ΔT₂₅% is 15 ns, the delay optical path length L(1) is calculated by: L(1)=ΔT_{50%}×c=15 ns×0.3 m/ns=4.5 m.

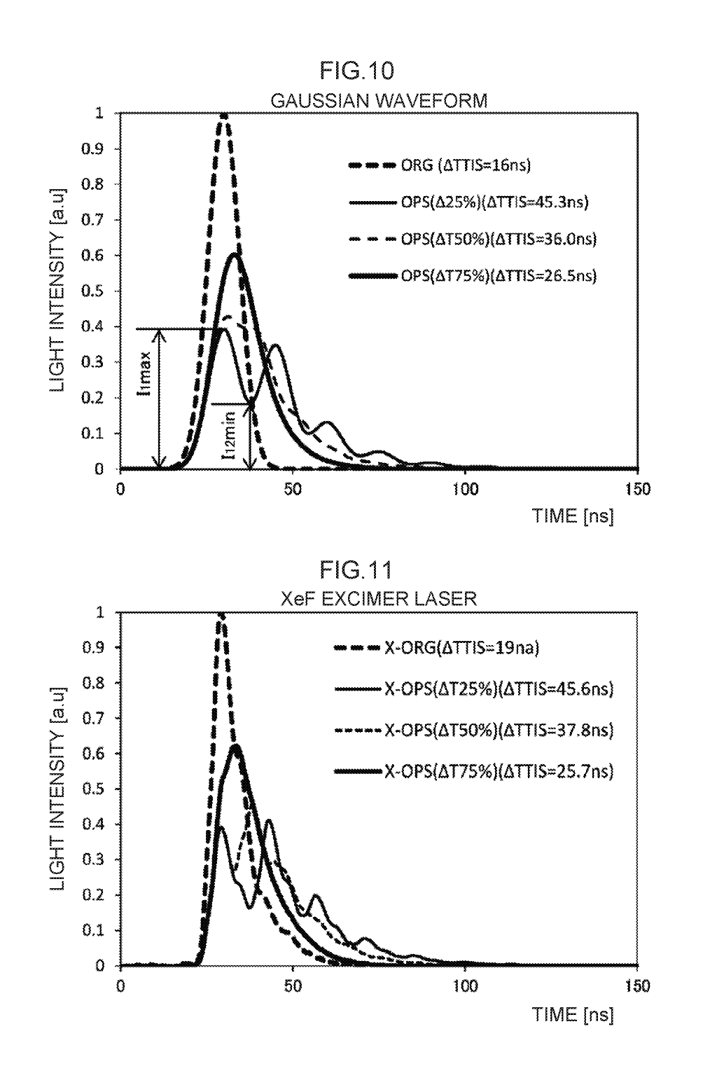

In FIGS. 7 to 9, the output waveform OPS of ΔT_{75%}, the output waveform OPS of ΔT_{50%}, and the output waveform OPS of ΔT_{25%} are illustrated by waveforms in a state where each circulation light PS is divided. In FIG. 10, the output waveform OPS of ΔT_{75%}, the output waveform OPS of ΔT_{50%}, and the output waveform OPS of ΔT_{25%} are illustrated by a waveform in a state where each circulation light PS is synthesized. In FIG. 10, the input waveform ORG is indicated by a thick broken line, the output waveform OPS of ΔT_{75%} is indicated by a thick solid line, the output waveform OPS of ΔT_{50%} is indicated by a thin broken line, and the output waveform OPS of ΔT_{25%} is indicated by a thin solid line.

When the TIS pulse time width ΔT_{TIS} is calculated based on each output waveform OPS of FIG. 10, ΔT_{TIS} is 26.5 ns in the case of the output waveform OPS of ΔT_{75%}, ΔT_{TIS} is 36.0 ns in the case of the output waveform OPS of ΔT_{50%},and ΔT_{TIS} is 45.3 ns in the case of the output waveform OPS of ΔT_{25%}. With ΔT_{TIS} being 16 ns in the input waveform ORG, the pulse time width of each output waveform OPS has stretched by using the OPS 41A.

When a comparison is made among the TIS pulse time widths ΔT_{TIS} of the respective output waveforms OPS, the TIS pulse time width ΔT_{TIS} of the output waveform OPS of ΔT_{25%} is the maximum width of 45.3 ns, and the TIS pulse time width ΔT_{TIS} of the output waveform OPS of ΔT_{75%} is the minimum width of 26.5 ns.

The output waveform OPS of ΔT_{25%} is a waveform in case that the largest delay optical path length L(1) is set among the three output waveforms OPS. For this reason, the time difference between each circulation light PS becomes maximal, so that the TIS pulse time width ΔT_{TIS} stretches more than in the other output waveforms OPS, in the output waveform OPS of ΔT_{25%}. On the other hand, due to a large time difference between each circulation light PS, a valley between the peaks is likely to occur as compare to other output waveforms OPS.

In contrast, the output waveform OPS of ΔT_{75%} is an output waveform in case that the smallest delay optical path length L(1) is set. Hence, the time difference between each circulation light PS becomes minimal. In the output waveform OPS of ΔT_{75%}, contrary to the output waveform OPS of ΔT_{25%}, a valley is less likely to occur than the other output waveforms, but TIS pulse time width ΔT_{TIS} becomes minimal. The output waveform OPS of ΔT_{50%} that is a waveform in case that the intermediate delay optical path length L(1) is set, and the TIS pulse time width ΔT_{TIS} becomes an intermediate length of 36.0 ns.

Further, when a comparison is made among the light intensity ratios Imr of the respective output waveforms OPS, the following is found. First, in the output waveform OPS of ΔT_{75%} in the condition of the delay optical path length L(1) being minimum, the number of peaks is one and there is thus no valley between peaks. Therefore, I₁max which is the maximum value of the light intensity of the first peak coincides with I₁₂min which is the minimum value in the valley, and the light intensity ratio Imr of the output waveform OPS of ΔT_{75%} (=I₁₂min/I₁max, see the above expression (2)) becomes 100%. Also in the output waveform OPS of ΔT_{50%} with the delay optical path length L(1) in an intermediate condition, there is a little valley between the peaks, and the light intensity ratio Imr of the output waveform OPS of ΔT_{50%} also shows a value of about 90% or higher.

In contrast, in the output waveform OPS of ΔT_{25%} in the condition of the delay optical path length L(1) being maximum, the first peak and the second peak clearly exist. However, as compared to the comparative example illustrated in FIG. 4, the decrease in light intensity in the valley between the peaks is small. Specifically, the light intensity ratio Imr of the output waveform OPS of ΔT_{25%} is about 47.6%.

As illustrated in FIG. 10, the TIS pulse time width ΔT_{TIS} of each output waveform OPS according to the first embodiment has stretched more than the input waveform ORG, but is shorter than 55 ns being the TIS pulse time width ΔT_{TIS} of the output waveform OPS according to the comparative example illustrated in FIG. 4. However, the light intensity ratio Imr of each output waveform OPS according to the first embodiment is high as compared to the comparative example illustrated in FIG. 4.

3.3 Effect of OPS Device

As described above, by setting the delay optical path length L(1) of the OPS 41A corresponding to the first OPS and the OPS device in a range of: ΔT_{75%}×c≤L(1)≤ΔT_{25%}×c (the above expression (3)), the decrease in light intensity can be suppressed. That is, it is possible to stretch the pulse time width while increasing the light intensity ratio Imr. As a result, it is possible to obtain an effect in which re-solidification of the amorphous silicon in the melted state is prevented to increase the grain size of crystal of the polycrystalline silicon, during irradiation with pulse laser light.

3.4 Example of XeF Excimer Laser

FIG. 11 is a graph of an example according to the XeF excimer laser using XeF as the laser medium of the master oscillator MO. In the present example, an input waveform of pulse laser light, which is output from the master oscillator MO and incident on the OPS 41A, is an input waveform X-ORG illustrated in FIG. 11. In FIG. 11, similarly to each output waveform OPS illustrated in FIG. 10, each output waveform X-OPS is an output waveform calculated by setting the delay optical path length L(1) of the OPS 41A based on a pulse full-width of the input waveform X-ORG.

An output waveform X-OPS of ΔT_{25%} indicated by a thin solid line in FIG. 11 is an output waveform in a case where the delay optical path length L(1) corresponding to the pulse full-width ΔT_{25%} of the input waveform X-ORG is ΔT_{25%}×c. In the input waveform X-ORG, since the pulse till-width ΔT_{25%} is 14.2 ns, the delay optical path length L(I.) is calculated by: L(1)=ΔT_{25%}×c=14.2 ns×0.3 m/ns=4.26 m.

An output waveform X-OPS of ΔT_{50%} indicated by a thin broken line in FIG. 11 is an output waveform in a case where the delay optical path length L(1) corresponding to the pulse full-width ΔT_{50%} of the input waveform X-ORG is ΔT_{50%}×c. In the input waveform X-ORG, since the pulse full-width ΔT_{50%} is 9.7 ns, the delay optical path length L(1) is calculated by: L(1)=ΔT_{50%}×c=9.7 ns×0.3 m/ns=2.91 m.

An output waveform X-OPS of ΔT_{75%} indicated by a thick solid line in FIG. 11 is an output waveform in a case where the delay optical path length L(1) corresponding to the pulse full-width ΔT_{75%} of the input waveform X-ORG is ΔT_{75%}×c. In the input waveform X-ORG, since the pulse full-width ΔT_{75%} is 4.4 ns, the delay optical path length L(1) is calculated by: L(1)=ΔT_{75%}×c=4.4 ns×0.3 m/ns=1.32 m.

The TIS pulse time width ΔT_{TIS} is 19 ns in the input waveform X-ORG. ΔT_{TIS} is 45.6 ns in the output waveform X-OPS of ΔT_{25%}. ΔT_{TIS} is 37.8 ns in the output waveform X-OPS of ΔT_{50%}, and ΔT_{TIS} is 25.7 ns in the output waveform X-OPS of ΔT_{75%}. Meanwhile, the decrease in light intensity between the first and second peaks is the maximum among the output waveforms X-OPS, in the output waveform X-OPS of ΔT_{25%} in FIG. 11. Also, the decrease in light intensity between the peaks has been suppressed in this output waveform X-OPS of ΔT_{25%}, as compared to the comparative example illustrated in FIG. 4. Specifically, the light intensity ratio Imr of the output waveform X-OPS of ΔT_{25%} is about 42.6%, and the light intensity ratio Imr is higher than that of the comparative example illustrated in FIG. 4.

As described above, it is possible to stretch the pulse time width while increasing the light intensity ratio Imr by setting the delay optical path length L(1) of the OPS 41A in the range of: ΔT_{75%}×c≤L(1)≤ΔT_{25%}×c (the above expression (3)), in the example of the XeF excimer laser. As a result, it is possible to obtain an effect in which re-solidification of the amorphous silicon in the melted state is prevented to increase the grain size of crystal of the polycrystalline silicon during irradiation with pulse laser light.

3.5 Others

The description has been given by using the example where the OPS device configured by the OPS 41A is disposed between the master oscillator MO and the pulse energy measuring unit 63 in the laser anneal device of the first embodiment, but the OPS device may be disposed at another position. For example, the OPS device may not be disposed in the laser device 3 but may be disposed on the optical path of the pulse laser light between the laser device 3 and the anneal device 4. Alternatively, the OPS device may be disposed, for example, inside the anneal device 4, such as at the preceding stage to the slit 16 (cf. FIG. 1) of the anneal device 4.

### 4. Laser Device of Second Embodiment and Laser Anneal Device Using the Same

4.1 Configuration

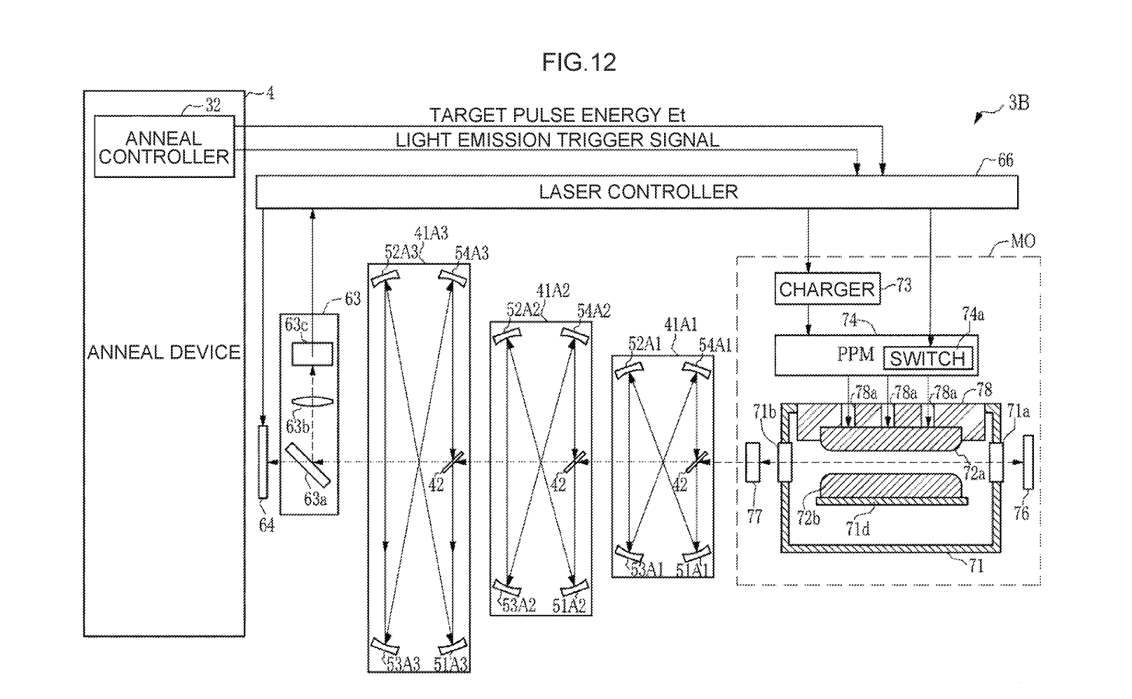

FIG. 12 schematically illustrates a configuration of a laser anneal device according to a second embodiment. The laser anneal device of the second embodiment includes a laser device 3B in place of the laser device 3A of the laser anneal device of the first embodiment illustrated in FIG. 5. The difference between the laser device 3B of the second embodiment and the laser device 3A of the first embodiment is that the number of OPSs 41A included in the OPS device. In the laser device 3B of the second embodiment, a plurality of OPSs 41A are provided. The OPS device in the laser device 3B of the second embodiment includes a first OPS 41A1, a second OPS 41A2, and a third OPS 41A3, and the OPS device is configured by three OPSs 41A. Since the other constituents are similar to those of the laser device 3A of the first embodiment, the same constituents are denoted by the same numerals, and the difference will be mainly described below.

The first to third OPSs 41A1, 41A2, 41A3 are arranged in series on an optical path of pulse laser light. The first OPS 41A1 is configured by the beam splitter 42 and first to fourth concave mirrors 51A1 to 54A1. The second OPS 41A2 is configured by the beam splitter 42 and first to fourth concave mirrors 51A2 to 54A2. The third OPS 41A3 is configured by the beam splitter 42 and first to fourth concave mirrors 51A3 to 54A3. The delay optical path length L(1) is the smallest and the delay optical path length L(3) is the largest, among the delay optical path length L(1) of the first OPS 41A1, the delay optical path length L(2) of the second OPS 41A2, the delay optical path length L(3) of the third OPS 41A3. That is, the relationship represented by: delay optical path length L(1)<delay optical path length L(2)<delay optical path length L(3), is satisfied.

The range of the delay optical path length L(1) is similar to that of the OPS 41A of the first embodiment and is set in the range of: ΔT_{75%}×c≤L(1)≤ΔT_{25%}×c (the above expression (3)). The delay optical path length L(2) and the delay optical path length L(3) are set with the delay optical path length L(1) taken as a reference. The delay optical path length L(2) is set twice as large as the delay optical path length L(1), namely, the delay optical path length L(2) is 2×L(1). The delay optical path length L(3) is set twice as large as the delay optical path length L(2), namely, the delay optical path length L(3) is 2×L(2).

As described above, when the OPS device includes n OPSs including the second to n-th OPSs 41A2 to 41An in addition to the first OPS 41A1, a delay optical path length L(k) of a k-th OPS 41Ak is preferably set so as to satisfy a condition shown in the following expression (4):

L(k)=2×L(k−1) (4),

where k is from 2 to n, both inclusive, and n is an integer equal to or larger than 2.

The delay optical path length L(1) of the first OPS 41A1 is set by a focal distance F of the first to fourth concave mirrors 51A1 to 54A1 and selection of an arrangement interval corresponding to the focal distance F. The delay optical path length L(2) of the second OPS 41A2 is set by a focal distance F of the first to fourth concave mirrors 51A2 to 54A2 and selection of an arrangement interval corresponding to the focal distance F. The delay optical path length L(3) of the third OPS 41A3 is set by a focal distance F of the first to fourth concave mirrors 51A3 to 54A3 and selection of an arrangement interval corresponding to the focal distance F.

4.2 Action of OPS Device

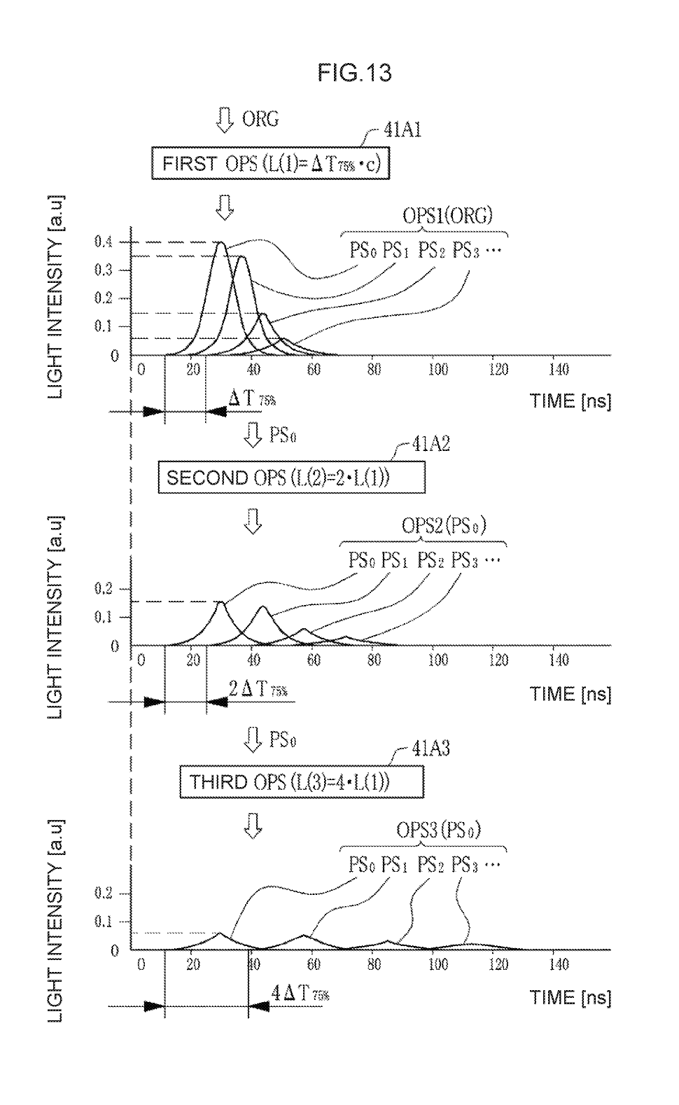

FIG. 13 illustrates shifts of the output waveform OPS in the case of using the three stages of OPSs which are the first to third OPSs 41A1 to 41A3. In FIG. 13, the delay optical path length L(1) of the first OPS 41A1 is set to the pulse full-width ΔT_{75%}×c of the input waveform ORG. Therefore, when the input waveform ORG is incident on the first OPS 41A1, subsequently to the zero-circulation light PS₀ which is output without through the delay optical path, the pulse light is output in order of the one-circulation light PS₁, the two-circulation light PS₂, . . . , with intervals ofΔT_{75%}. These circulation light beams PS are synthesized to become an output waveform OPS1 of the input waveform ORG.

Next, when the zero-circulation light PS₀ included in the output waveform OPS1 is incident on the second OPS 41A2, this is further divided into zero-circulation light PS₀, one-circulation light PS₁, two-circulation light PS₂, . . . , and each output as an output waveform OPS2. However, since the delay optical path length L(2) of the second OPS 41A2 is 2×L(1), the time difference between each circulation light PS, output from the second OPS 41A2, is 2×ΔT_{75%}.

In FIG. 13, the output waveform OPS2 is an output waveform with respect to the input of the zero-circulation light PS₀ among the circulation light PS included in the output waveform OPS1 of the input waveform ORG. Although not illustrated in FIG. 13 so as to avoid complication of the drawing, naturally, the one-circulation light PS₁, the two-circulation light PS₂, . . . , included in the output waveform OPS1 of the input waveform ORG are also input sequentially into the second OPS 41A2. The output waveform OPS2 of the one-circulation light PS₁, the output waveform OPS2 of the two-circulation light PS₂, . . . , with respect to the above circulation light are also output from the second OPS 41A2.

Next, when the zero-circulation light PS₀ included in the output waveform OPS2 is incident on the third OPS 41A3, this is further divided into zero-circulation light PS₀, one-circulation light PS₁, two-circulation light PS₂, . . . , and each output as an output waveform OPS3. However, since the delay optical path length L(3) of the third OPS 41A3 is represented by L(3)=2×L(2)=4×L(1), the time difference between each circulation light PS having been output from the third OPS 41A3, is 4×ΔT_{75%}.

Further, the output waveform OPS3 illustrated in FIG. 13 is an output waveform with respect to the input of the zero-circulation light PS₀ among the circulation light PS included in the output waveform OPS2. Although not illustrated, similarly to the second OPS 41A2, the one-circulation light PS₁, the two-circulation light PS₂, . . . , included in the output waveform OPS2 are also input sequentially into the third OPS 41A3. The output waveform OPS3 of the one-circulation light PS₁, the output waveform OPS3 of the two-circulation light PS₂, . . . , are also output from the third OPS 41A3.

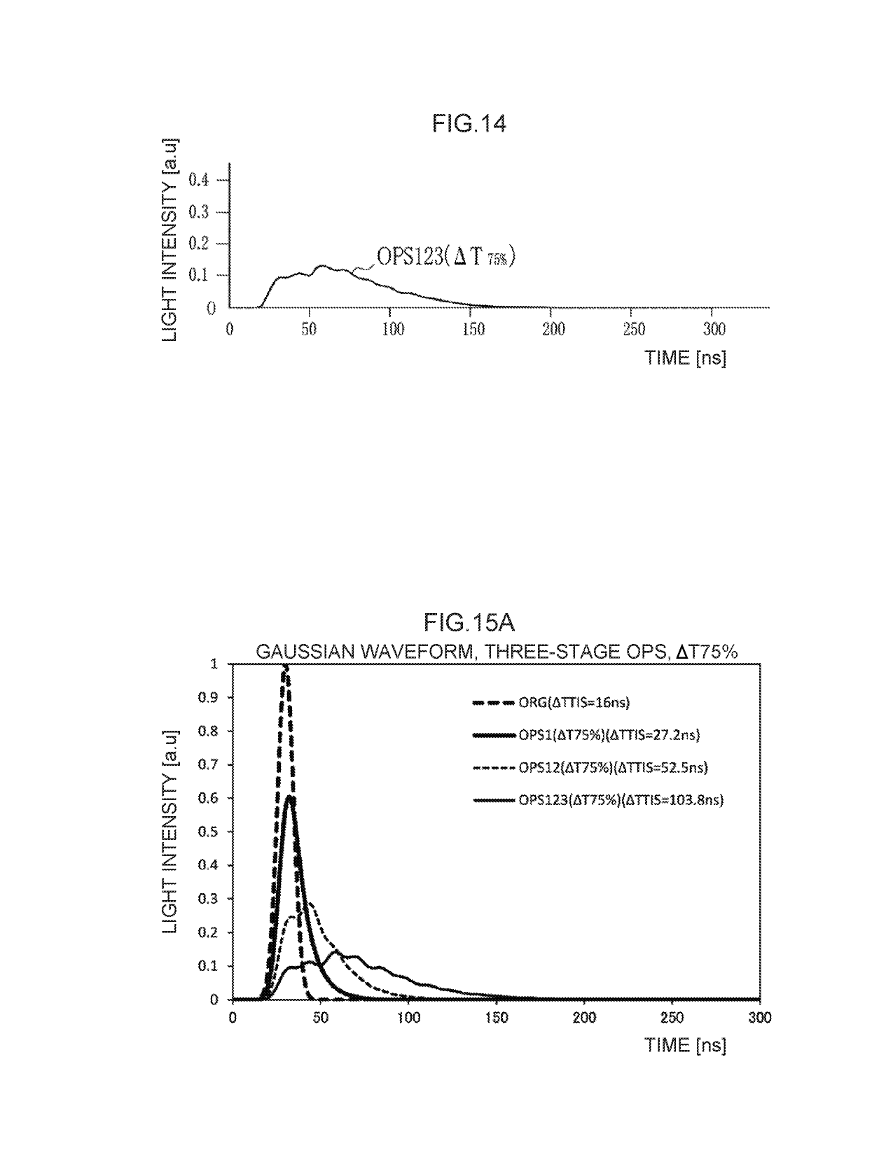

A waveform formed by synthesizing the output waveform OPS3 of the zero-circulation light PS₀, the output waveform OPS3 of the one-circulation light PS₁, the output waveform OPS3 of the two-circulation light PS₂, . . . becomes an output waveform that is output from the OPS device configured by the first to third OPSs 41A1 to 41A3. This output waveform becomes an output waveform OPS123 of ΔT_{75%} illustrated in FIG. 14.

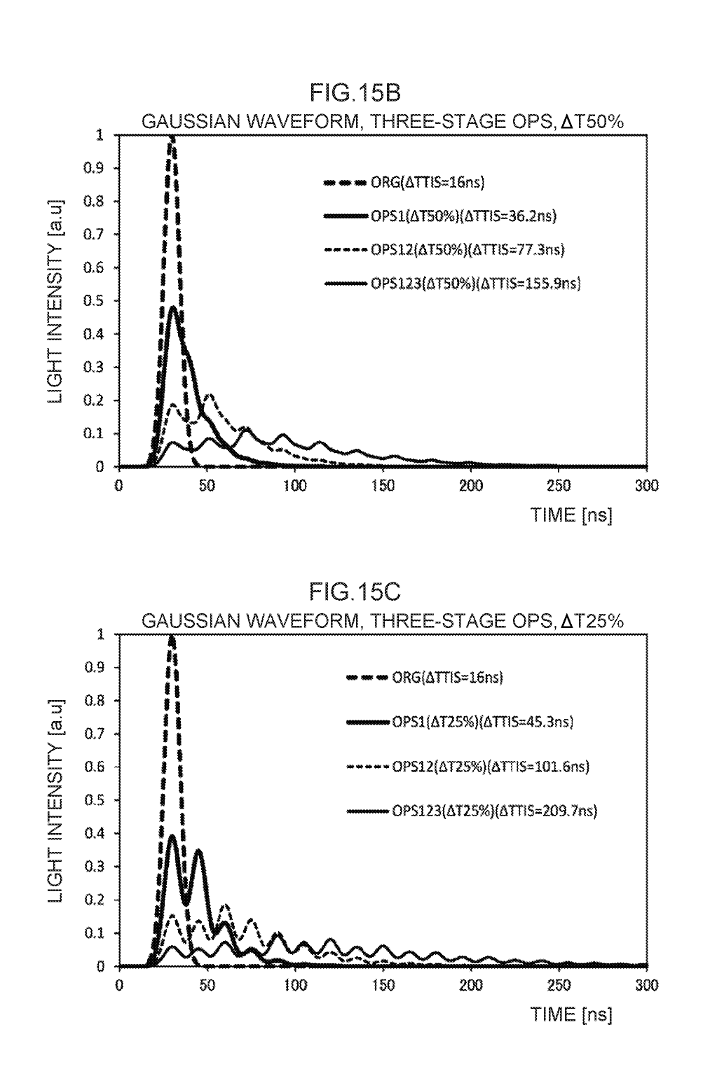

Graphs illustrated in FIGS. 15A to 15C each represents an input waveform ORG assumed to be a Gaussian waveform and output waveforms OPS in case that the delay optical path length L(1) and the number of stages of the OPS 41A are changed, the output waveforms OPS having been calculated based on the input waveform ORG, in the laser anneal device of the second embodiment illustrated in FIG. 12.

The graph illustrated in FIG. 15A is the output waveform OPS in the case of setting the delay optical path length L(1) of the first OPS 41A1 to ΔT_{75%}×c. In the input waveform ORG, the pulse full-width ΔT_{75%} is 6.8 ns, and hence the delay optical path length L(1) is set as follows: L(1)=ΔT_{75%}×c=6.8 ns×0.3 m/ns=2.04 m. The delay optical path length L(2) of the second OPS 41A2 is set as follows: L(2)=2×L(1)=2×2.04 m=4.08 m. The delay optical path length L(3) of the third OPS 41A3 is set as follows: L(3)=4×L(1)=4×2.04 m=8.16 m.

The graph illustrated in FIG. 15B is the output waveform OPS in the case of setting the delay optical path length L(1) to ΔT_{50%}×c. In the input waveform ORG, the pulse full-width ΔT_{50% is} 10.6 ns, and hence the delay optical path length L(1) is set as follows: L(1) ΔT_{50%}×c=10.6 ns×0.3 m/ns 3.18 m. The delay optical path length L(2) of the second OPS 41A2 is set as follows: L(2)=2×L(1)=2×3.18 m=6.36 m. The delay optical path length L(3) of the third OPS 41A3 is set as follows: L(3)=2×L(2)=2×6.36 m=12.72 m.

The graph illustrated in FIG. 15C is the output waveform OPS in the case of setting the delay optical path length L(1) to ΔT_{25%}×c. In the input waveform ORG, the pulse full-width ΔT_{25%} is 15 ns, and hence the delay optical path length L(1) is set as follows: L(1)=ΔT_{25%}×c=15 ns×0.3 m/ns=4.5 m. The delay optical path length L(2) of the second OPS 41A2 is set as follows: L(2)=2×L(1)=2×4.5 m=9.0 m. The delay optical path length L(3) of the third OPS 41A3 is set as follows: L(3)=2×L(2)=2×9.0 m=18 m.

In FIGS. 15A to 15C, the input waveform ORG indicated by a thick broken line is in common, and the TIS pulse time width ΔT_{TIS} of the input waveform ORG is 16 ns.

In the graph illustrated in FIG. 15A, an output waveform OPS 1 indicated by a thick solid line is an output waveform of the one-stage OPS device including only one first OPS 41A1 similarly to the first embodiment. An output waveform OPS12 indicated by a thin broken line is an output waveform of the two-stage OPS device in which the first OPS 41A1 and the second OPS 41A2 are arranged in series. An output waveform OPS123 indicated by a thin solid line is an output waveform of the three-stage OPS device in which the first to third OPSs 41A1 to 41A3 are arranged in series as illustrated in FIG. 12 and is the same as the output waveform illustrated in FIG. 14.

In each output waveform OPS in the case of ΔT_{75%} illustrated in FIG. 15A, the TIS pulse time width ΔT_{TIS} is 27.2 ns in the output waveform OPS1 of the one-stage OPS device. ΔT_{TIS} is 52.5 ns in the output waveform OPS12 of the two-stage OPS device. ΔT_{TIS} is 103.8 ns in the output waveform OPS123 of the three-stage OPS device. The pulse time width of any output waveform OPS is longer than 16 ns which is the TIS pulse time width ΔT_{TIS} of the input waveform ORG. Further, since there is almost no decrease in light intensity between the first and second peaks in each of the output waveforms OPS1, OPS12, OPS123 in the case of ΔT_{75%}, the light intensity ratio Imr is higher than that in the comparative example illustrated in FIG. 4.

In each output waveform OPS in the case of ΔT_{50%} illustrated in FIG. 15B, similarly to FIG. 15A, an output waveform OPS1 indicated by a thick solid line is an output waveform of the one-stage OPS device including only the first OPS 41A1. An output waveform OPS12 indicated by a thin broken line is an output waveform of the two-stage OPS device configured by the first OPS 41A1 and the second OPS 41A2. An output waveform OPS123 indicated by a thin solid line is an output waveform of the three-stage OPS device configured by the first to third. OPSs 41A1 to 41A3.

In each output waveform OPS in the case of ΔT_{50%} illustrated in FIG. 15B, the TIS pulse time width ΔT_{TIS} is 36.2 ns in the output waveform OPS 1. ΔT_{TIS} is 77.3 ns in the output waveform OPS1.2, and ΔT_{TIS} is 155.9 ns in the output waveform OPS123. The pulse time width of any output waveform OPS is longer than 16 ns which is the TIS pulse time width ΔT_{TIS} of the input waveform ORG. Further, in each of the output waveforms OPS1, OPS12, OPS123 in the case of ΔT_{50%}, the decrease in light intensity between the first and second peaks has been suppressed and the light intensity ratio Imr is higher than that of the output waveform OPS of the comparative example illustrated in FIG. 4.

In each output waveform OPS in the case of ΔT_{25%} illustrated in FIG. 15C, similarly to FIGS. 15A and 15B, an output waveform OPS1 indicated by a thick solid line is an output waveform of the one-stage OPS device. An output waveform OPS12 indicated by a thin broken line is an output waveform of the two-stage OPS device. An output waveform OPS123 indicated by a thin solid line is an output waveform of the three-stage OPS device.

In each output waveform OPS in the case of ΔT_{25%} illustrated in FIG. 15C, the TIS pulse time width ΔT_{TIS} is 45.3 ns in the output waveform OPS1. ΔT_{TIS} is 101.6 ns in the output waveform OPS12, and ΔT_{TIS} is 209.7 ns in the output waveform OPS123. The pulse time width of any output waveform OPS is longer than 16 ns which is the TIS pulse time width ΔT_{TIS} of the input waveform ORG. Further, the decrease in light intensity between the first and second peaks has been suppressed and the light intensity ratio Imr is high as compared to the output waveform OPS of the comparative example illustrated in FIG. 4, in each of the output waveforms OPS1, OPS12, OPS123 in the case of ΔT_{25%}.

4.3 Effect

As described above, as illustrated in FIGS. 15A to 15C, it is possible to stretch the pulse time width of the output waveform OPS123 while increasing the light intensity ratio Imr thereof as compared to the output waveform OPS of the comparative example illustrated in FIG. 4.

Further, the OPS device according to the first embodiment is the one-stage OPS device configured by one OPS 41A corresponding to the first OPS. In contrast, the OPS device according to the second embodiment is the three-stage OPS device including the second and third OPSs 41A2, 41A3 in addition to the first OPS 41A1. Since the OPS device according to the second embodiment is configured by such three stages of OPSs 41A1 to 41A3, it is possible to stretch the pulse time width while increasing the light intensity ratio Imr as compared to the first embodiment.

The comparison among FIGS. 15A to 15C reveals the following. In the case of the OPS device being configured by a plurality of stages of OPSs 41A, the shorter the delay optical path length L(1) of the first OPS 41A1, the more the decrease in light intensity is suppressed. The delay optical path length L(1) is the smallest in the case of the pulse full-width ΔT₇₅% of FIG. 15A. However, the TIS pulse time width ΔT_{TIS} becomes short. Further, as indicated by the respective output waveforms OPS1, OPS12, OPS123 of FIGS. 15A to 15C, the larger the number of OPS 41A becomes, the more the decrease in light intensity is suppressed and the longer the TIS pulse time width ΔT_{TIS} becomes. However, the larger the number of OPSs 41A becomes, the more the light intensity attenuates.

The respective delay optical path lengths L(1) to L(3) of the first to third OPSs 41A1 to 41A3 are represented by: L(1), L(2)=2×L(1) and L(3)=2×L(2), having been set so as to satisfy the condition represented by: L(k)=2×L(k−1) (the above expression (4)). By setting the delay optical path length L(k) as in the present example, it is possible to stretch the pulse time width while increasing the light intensity ratio Imr with a relatively small number of OPSs. This suppresses the increase in the number of OPSs, thus suppressing the attenuation of the light intensity.

The delay optical path length L(1) of the first OPS 41A1 and the number of OPS 41A are selected as appropriate in consideration of the light intensity of the input waveform ORG output by the master oscillator MO and the light intensity, the pulse time width, and the like of pulse laser light required in the anneal device 4.

4.4 Example 1 of XeF Excimer Laser

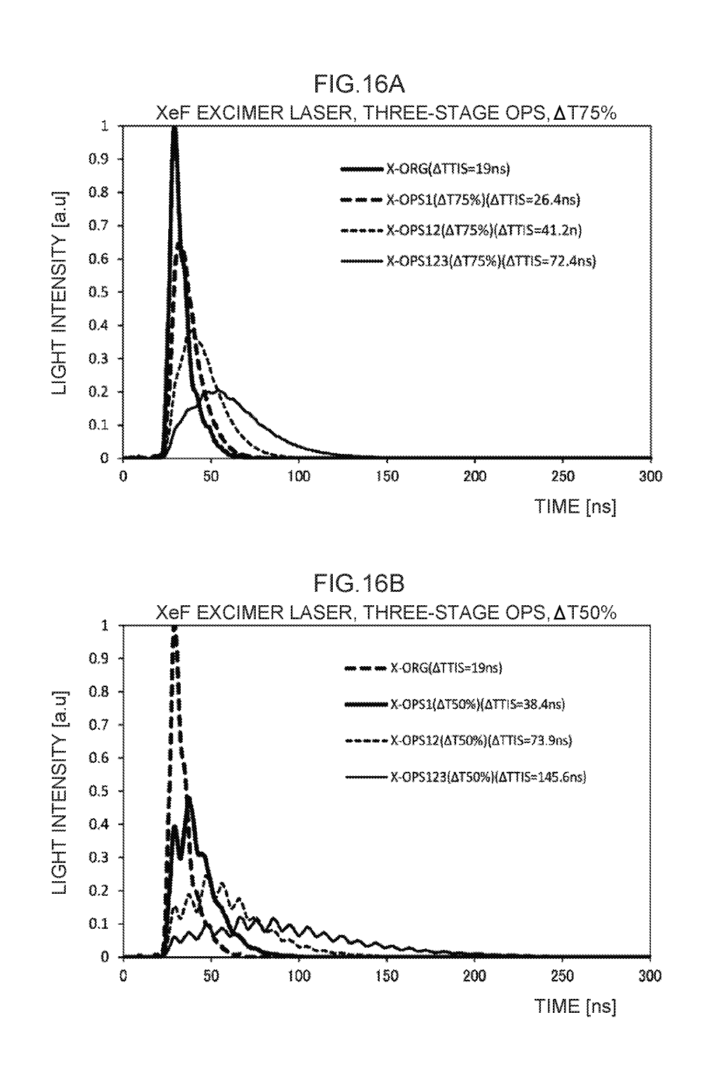

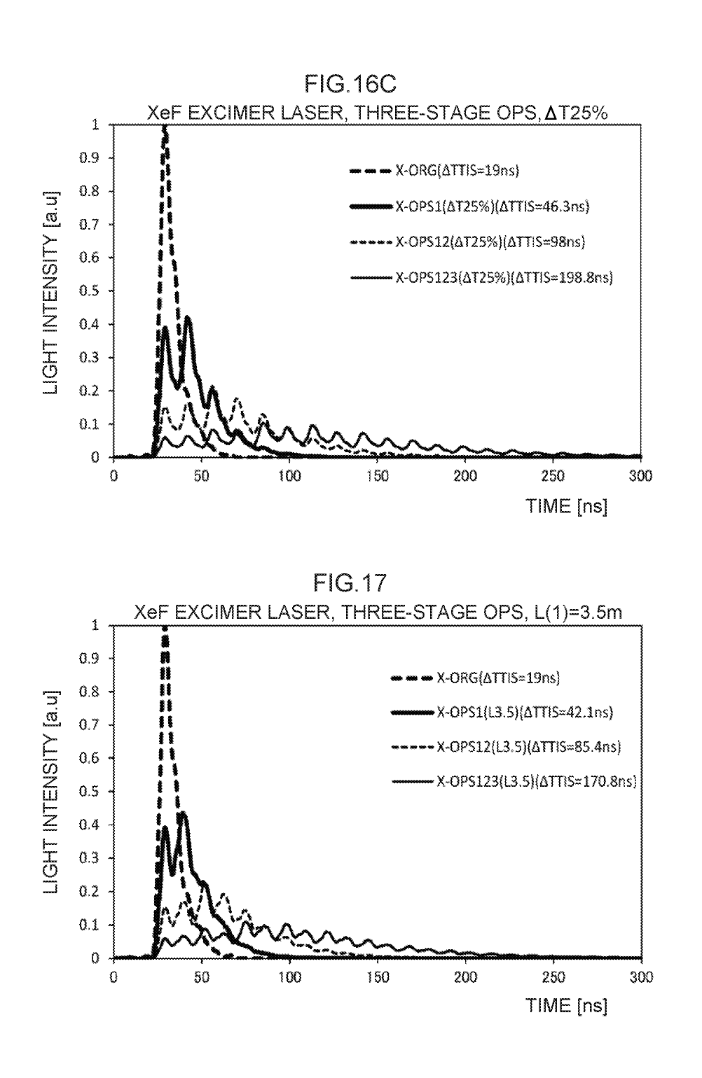

FIGS. 16A to 16C illustrate graphs of Example 1 according to the XeF excimer laser using XeF as the laser medium of the master oscillator MO. In the present Example 1. an input waveform of pulse laser light output from master oscillator MO and incident on the first OPS 41A is an input waveform X-ORG similar to that in FIG. 11.

The graphs of FIGS. 16A to 16C are different from the graphs of FIGS. 15A to 15C in that the input waveform ORG has changed to the input waveform X-ORG measured with actual equipment using XeF as the laser medium. With the input waveform X-ORG, naturally, the output waveforms X-OPS1, X-OPS12, X-OPS123 of FIGS. 16A to 16C have respectively changed from the output waveforms of FIGS. 15A to 15C. The combinations of the line types, conditions, and the like of the graphs except for the above input waveforms in FIGS. 16A to 16C are respectively similar to those in FIGS. 15A to 15C.

The graph illustrated in FIG. 16A is an output waveform X-OPS in the case of setting the delay optical path length L(1) of the first OPS 41A1 to ΔT_{75%}×c. In the input waveform X-ORG, since the pulse full-width ΔT_{75%} is 4.4 ns, the delay optical path length L(1) is set as follows: L(1)=ΔT_{75%}×c=4.4 ns×0.3 m/ns=1.32 m. The delay optical path length L(2) of the second OPS 41A2 is set as follows: L(2)=2×L(1)=2×1.32 m=2.64 m. The delay optical path length L(3) of the third OPS 41A3 is set as follows: L(3)=2×L(2)=2×2.64 m=5.28 m.

The graph illustrated in FIG. 16B is an output waveform X-OPS in the case of setting the delay optical path length L(1) to ΔT_{50%}×c. In the input waveform X-ORG, since the pulse full-width ΔT_{50%} is 9.7 ns. the delay optical path length L(1) is represented by: L(1)=ΔT_{50%}×c=9.7 ns×0.3 m/ns=2.91 m. The delay optical path length L(2) of the second OPS 41A2 is set as follows: L(2)=2×L(1)=2×2.91 m=5.82 m. The delay optical path length L(3) of the third OPS 41A3 is set as follows: L(3)=2×L(2)=2×5.82 m=11.64 m.

The graph illustrated in FIG. 16C is the output waveform OPS in the case of setting the delay optical path length L(1) to ΔT_{25%}×c. In the input waveform ORG, the pulse full-width ΔT_{25%} is 14.2 ns, and hence the delay optical path length L(1) is set as follows: L(1)=ΔT_{25%}×c=14.2 ns×0.3 m/ns=4.26 m. The delay optical path length L(2) of the second OPS 41A2 is set as follows: L(2)=2×L(1)=2×4.26 m=8.52 m. The delay optical path length L(3) of the third OPS 41A3 is set as follows: L(3)=2×L(2)=2×8.52 m=17.04 m.

In FIGS. 16A to 16C, the TIS pulse time width ΔT_{TIS} of the input waveform X-ORG is 19 ns.

In each output waveform in the case of ΔT_{75%} illustrated, in FIG. 16A, similarly to FIG. 15A, an output waveform X-OPS1 indicated by a thick solid line is an output waveform of the one-stage OPS device including only the first OPS 41A1. An output waveform X-OPS12 indicated by a thin broken line is an output waveform of the two-stage OPS device configured by the first OPS 41A1 and the second OPS 41A2. An output waveform X-OPS123 indicated by a thin solid line is an output waveform of the three-stage OPS device configured by the first to third OPSs 41A1 to 41A3.

In each output waveform in the case of ΔT_{75%} illustrated in FIG. 16A, the TIS pulse time width ΔT_{TIS} is 26.4 ns in the output waveform X-OPS1. ΔT_{TIS} is 41.2 ns in the output waveform X-OPS12, and ΔT_{TIS} is 72.4 ns in the output waveform OPS123. The pulse time width of any output waveform OPS is longer than 19 ns which is the TIS pulse time width ΔT_{TIS} of the input waveform X-ORG. Further, since there is almost no decrease in light intensity between the first and second peaks in each of the output waveforms X-OPS1, X-OPS12, X-OPS123 in the case of ΔT_{75%}, the light intensity ratio Imr has been improved more than that in the comparative example illustrated in FIG. 4.

In each output waveform in the case of ΔT_{50%} illustrated in FIG. 16B, similarly to FIG. 15B, an output waveform X-OPS1 indicated by a thick solid line is an output waveform of the one-stage OPS device. An output waveform X-OPS12 indicated by a thin broken line is an output waveform of the two-stage OPS device. An output waveform X-OPS123 indicated by a thin solid line is an output waveform of the three-stage OPS device.

In each output waveform in the case of ΔT_{50%} illustrated in FIG. 16B, the TIS pulse time width ΔT_{TIS} is 38.4 ns in the output waveform X-OPS1. ΔT_{TIS} is 73.9 ns in the output waveform X-OPS12, and ΔT_{TIS} is 145.6 ns in the output waveform X-OPS123. The pulse time width of any output waveform X-OPS is longer than 19 ns which is the TIS pulse time width ΔT_{TIS} of the input waveform X-ORG. Further, in each of the output waveforms X-OPS1, X-OPS12, X-OPS123 in the case of ΔT_{50%}, the decrease in light intensity between the first and second peaks has been suppressed and the light intensity ratio Imr has been improved as compared to the output waveform OPS of the comparative example illustrated in FIG. 4 and the output waveform X-OPS of the first embodiment illustrated in FIG. 11.

In each output waveform in the case of ΔT_{25%} illustrated in FIG. 16C, similarly to FIG. 15C, an output waveform X-OPS1 indicated by a thick solid line is an output waveform of the one-stage OPS device. An output waveform X-OPS12 indicated by a thin broken line is an output waveform of the two-stage OPS device. An output waveform X-OPS123 indicated by a thin solid line is an output waveform of the three-stage OPS device.

In each output waveform in the case of ΔT_{25%} illustrated in FIG. 16C, the TIS pulse time width ΔT_{TIS} is 46.3 ns in the output waveform X-OPS1. ΔT_{TIS} is 98 ns in the output waveform X-OPS12, and ΔT_{TIS} is 198.8 ns in the output waveform X-OPS123. The pulse time width of any output waveform X-OPS is longer than 19 ns which is the TIS pulse time width ΔT_{TIS} of the input waveform X-ORG. Further, in each of the output waveforms X-OPS1, X-OPS12, X-OPS123 in the case of ΔT_{25%}, the decrease in light intensity between the first and second peaks has been suppressed and the light intensity ratio Imr has been improved as compared to the output waveform OPS of the comparative example illustrated in FIG. 4 and the output waveform X-OPS of the first embodiment illustrated in FIG. 11.

Also in Example 1 of the XeF excimer laser illustrated in FIG. 16A to 16C, similar effects to those in FIGS. 15A to 15C (cf. 4.3 above) are obtained.

4.5 Example 2 of XeF Excimer Laser

Example 2 of the XeF excimer laser illustrated in FIG. 17 is different from Example 1 of the XeF excimer laser in the settings of the delay optical path lengths L(1), L(2), L(3). The other constituents of the laser anneal device are similar to those in Example 1.

In present Example 2, the delay optical path length L(1) of the first OPS 41A1 is set as follows: L(1)=3.5 m. The delay optical path length L(2) of the second OPS 41A2 is set as follows: L(2)=2×L(1)=2×3.5 m=7 m, and the delay optical path length L(3) of the third OPS 41A3 is set as follows: L(3)=2×L(2)=2×7 m=14 m. Such set values of the delay optical path length L are values in a case where the delay optical path is configured in accordance with a focal distance F of a concave mirror which is relatively easy to obtain as each of the first to fourth concave mirrors 51A to 54A constituting the delay optical path.

The delay optical path length L(1) of Example 1 illustrated in FIGS. 16A to 16C is ΔT_{25%}×c=14.2 ns×0.3 m/ns=4.26 m in the case of using the pulse full-width ΔT_{25%} of the input waveform X-ORG, and ΔT_{50%}×c=9.7 ns×0.3 m/ns=2.91 m in the case of using the pulse full-width ΔT_{50%} of the input waveform X-ORG. The set value: the delay optical path length L(1)=3.5 m, in present Example 2 is between a value in the case of using the pulse full-width ΔT₂₅% of the input waveform X-ORG and a value in the case of using the pulse full-width ΔT_{50%} of the input waveform X-ORG.

In the graph in the case of L(1) being 3.5 m illustrated in FIG. 17, an output waveform X-OPS1 indicated by a thick solid line is an output waveform of the one-stage OPS device including only the first OPS 41A1. An output waveform X-OPS12 indicated by a thin broken line is an output waveform of the two-stage OPS device configured by the first OPS 41A1 and the second OPS 41A2. An output waveform X-OPS123 indicated by a thin solid line is an output waveform of the three-stage OPS device configured by the first to third OPSs 41A1 to 41A3.

In the graph in the case of L(1)=3.5 m illustrated in FIG. 17, the TIS pulse time width ΔT_{TIS} is ΔT_{TIS}=42.1 us in the output waveform X-OPS1. ΔT_{TIS} is 85.4 ns in the output waveform X-OPS12, and ΔT_{TIS} is 170.8 ns in the output waveform X-OPS123. The pulse time width of any output waveform X-OPS is longer than 19 ns which is the TIS pulse time width ΔT_{TIS} is of the input waveform X-ORG. Further, in each of the output waveforms X-OPS1, X-OPS12, X-OPS123 in the case of L(1)=3.5 m, the decrease in light intensity between the first and second peaks has been suppressed and the light intensity ratio Imr has been improved as compared to the output waveform OPS of the comparative example illustrated in FIG. 4 and the output waveform X-OPS of the first embodiment illustrated in FIG. 11. More specifically, the light intensity ratio Imr of Example 2 is about 50% or higher.

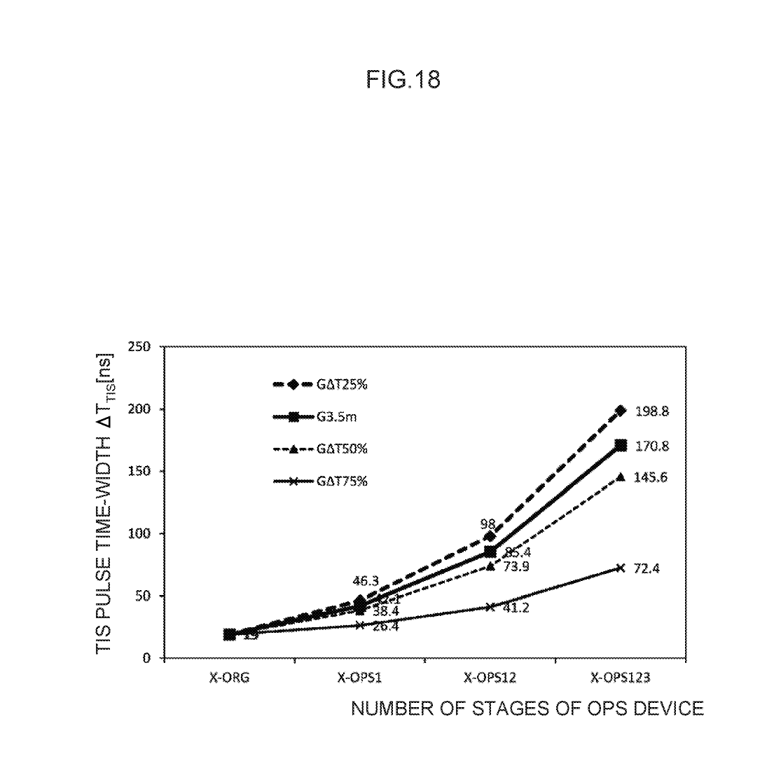

A graph illustrated in FIG. 18 is a graph taking the number of OPS stages as a horizontal axis and the TIS pulse time width ΔT_{TIS} as a vertical axis, and represents a change in TIS pulse time width ΔT_{TIS} in accordance with the number of OPS stages. A graph GΔT₂₅% indicated by a thick broken line is obtained by plotting 46.3 ns, 98 ns, and 198.8 ns which are TIS pulse time widths ΔT_{TIS} of the respective output waveforms X-OPS1, X-OPS12, X-OPS123 in the case of ΔT₂₅% illustrated in FIG. 16C, A graph G3.5 m indicated by a thick solid line is obtained by plotting 42.1 ns, 85.4 ns, and 170.8 ns which are TIS pulse time widths ΔT_{TIS} of the respective output waveforms X-OPS1, X-OPS12, X-OPS123 in the present example illustrated in FIG. 17.

A graph GΔT_{50%} indicated by a thin broken line is obtained by plotting 38.4 ns, 73.9 ns, and 145.6 ns which are TIS pulse time widths ΔT_{TIS} of the respective output waveforms X-OPS1, X-OPS12, X-OPS123 in the case of ΔT_{50%} illustrated in FIG. 16B. A graph GΔT_{75%} indicated by a thin solid line is obtained by plotting 26.4 ns, 41.2 ns, and 72.4 ns which are TIS pulse time widths ΔT_{TIS} of the respective output waveforms X-OPS1, X-OPS12, X-OPS123 in the case of ΔT_{75%} illustrated in FIG. 16C.

As apparent from each graph G illustrated in FIG. 18, the larger the delay-optical path length L(1) of the first OPS 41A1 becomes, and the larger the number of OPS stages becomes, the longer the TIS pulse time width ΔT_{TIS} can be made. By comparison among the graphs G illustrated in FIG. 18, it is possible to clearly grasp that the characteristic of present Example 2 indicated by the graph G3.5 m is located between the characteristic of the output waveform X-OPS of FIG. 16B, indicated by the graph GΔT_{50%}, and the characteristic of the output waveform X-OPS of FIG. 16C, indicated by the graph GΔT_{25%}. Also in present Example 2, similar effects to those in the embodiment of FIGS. 15A to 15C (cf above 4.3) are obtained.

4.6 Modified Example (OPS Device Configured by First to n-th OPSs)

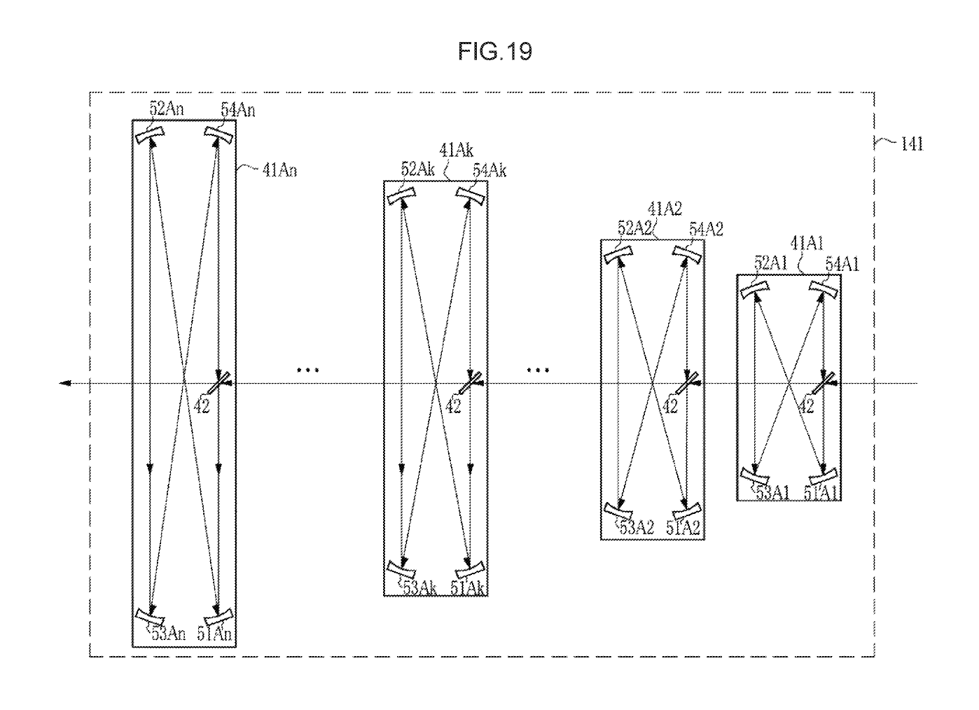

When the plural-stage OPS device is used as in an OPS device 141 illustrated in FIG. 19, the number of OPSs is not limited to three, but the OPS device is only required to be configured by two or more OPSs. In the present example, the OPS device 141 is configured by n OPSs which are the first OPS 41A1, the second OPS 41A2, . . . , the k-th OPS 41Ak, . . . , and the n-th OPS 41An.

In the OPS device 141 of FIG. 19, the delay optical path length L(1) of the first OPS 41A1 is set in the range of: ΔT_{75%}×c≤L(1)≤ΔT_{25%}×c (the above expression (3)) similarly to the three-stage OPS device illustrated in FIG. 12. Further, as shown in each example of the three-stage OPS device, when the OPS device is configured by n OPSs which are the second to n-th OPSs 41A2 to 41An in addition to the first OPS 41A1, the delay optical path length L(k) of the k-th OPS 41Ak is preferably set so as to satisfy the condition represented by: L(k)=2×L(k−1) (the above expression (4)), where k is from 2 to n, both inclusive, and n is an integer equal to or larger than 2. By making the delay optical path length L of the added OPS 41A larger, the effect of stretching the pulse time width is large as compared to the case of adding the OPS 41A with the same delay optical path length L(1) as that of the first OPS 41Al.

4.7. Others

In the case of using the plural-stage OPS device, the first to n-th OPSs 41A1 to 41An are arranged in ascending order of the delay optical path length L from the side of the master oscillator MO that is the laser oscillator, in the above example. However, the plurality of OPSs 41A may not be arranged in ascending order of the delay optical path length L. For example, the delay optical path length L may be arranged in descending order of the delay optical path length L, or may be arranged in order irrespective of the order of the delay optical path length L, such as the second OPS 41A2, the first OPS 41A1, and the third OPS 41A3. In whichever order the plurality of OPSs 41A are arranged, the effect of stretching the pulse time width and the effect of improving the light intensity ratio Imr are the same.

However, the OPSs 41A are preferably arranged in ascending order of the delay optical path length L from the master oscillator MO side, from the standpoint of maintenance. The reason for this is described below: pulse laser light with higher light intensity is incident on the OPS 41A closer to the master oscillator MO side, and hence optical elements such as the beam splitter 42 and the concave mirrors 51 A to 54A are thought to deteriorate earlier. The shorter the delay optical path length L becomes, the smaller the size of the OPS 41A becomes and the easier the replacement of the OPS 41A becomes. On the contrary, the larger the delay optical path length L becomes, the larger the size of the OPS 41A becomes and the more difficult the replacement of the OPS 41A becomes. Thus, it is possible to relatively extend durability of a large-sized OPS 41A with a large delay optical path length L, by arranging the OPSs 41A in ascending order of the delay optical path length L from the master oscillator MO side. This enables relative reduction in number of times of replacement of the OPS 41A which is large-sized and difficult to be replaced.

Further, in the case of adding the plurality of second to n-th OPSs 41A in addition to the first OPS 41A as in the above embodiment, it is preferable to add the OPSs 41A with larger delay optical path lengths L than the delay optical path length L(1) of the first OPS 41A. When the OPS 41A having a shorter delay optical path length than L(1) is provided, the effect of reducing the decrease in light intensity can be expected. However, the effect of stretching the pulse time width is hard to obtain as compared to the case of providing the OPS with a larger delay optical path length L than L(1). The larger the number of OPSs 41A becomes, the more the light intensity attenuates. For obtaining a high effect by using as small number of OPSs as possible, it is preferable to add the OPS with a larger delay optical path length L than L(1), in the case of adding the OPS.

### 5. Laser Device of Third Embodiment and Laser Anneal Device Using the Same

5.1 Configuration

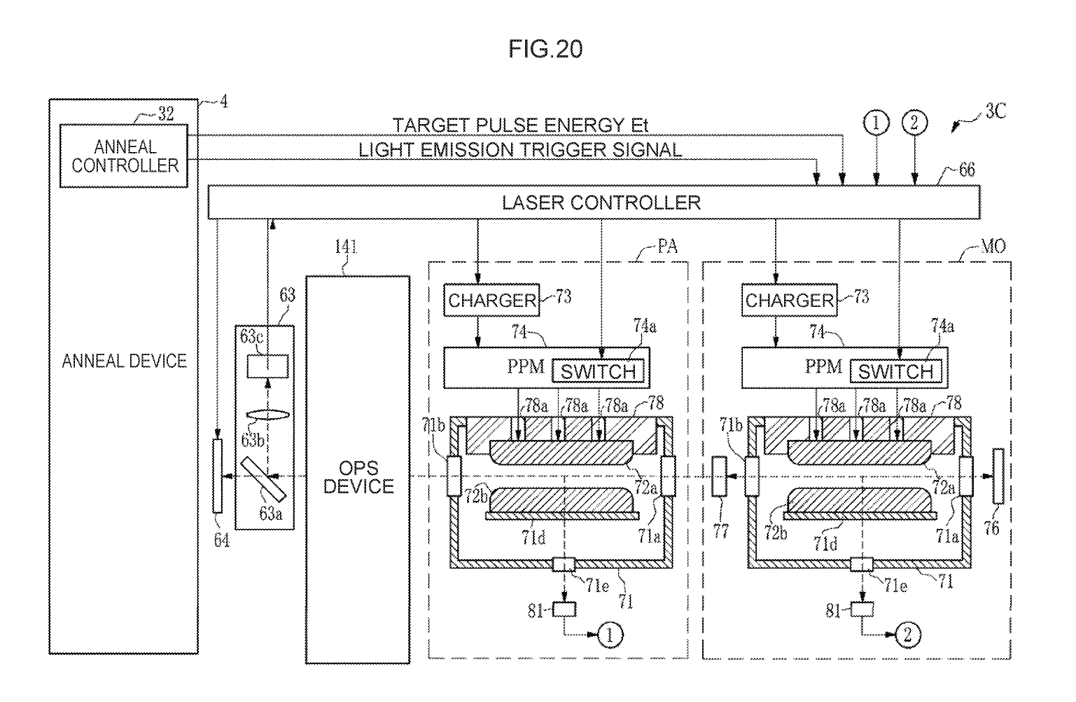

FIG. 20 schematically illustrates a configuration of a laser anneal device according to a third embodiment. The laser anneal device of the third embodiment includes a laser device 3C in place of the laser device 3B of the laser anneal device of the second embodiment illustrated in FIG. 12. The difference between the laser device 3C of the third embodiment and the laser device 3B according to the second embodiment is that the laser device 3C includes an amplifier PA in addition to the master oscillator MO being the laser oscillator. Such a laser device 3C is also called a MOPA system. An OPS device 141 in the laser device 3C is a three-stage OPS device similar to that in the laser device 3B. Since the other constituents are similar to those of the laser device 3B of the second embodiment, the same constituents are denoted by the same numerals, and the difference will be mainly described below.

The amplifier PA is disposed on an optical path of pulse laser light output from the output coupling mirror 77 of the master oscillator MO. Similarly to the master oscillator MO, the amplifier PA includes a laser chamber 71, a pair of electrodes 72a, 72b, a charger 73, and a pulse power module (PPM) 74. These constituents are similar to those included in the master oscillator MO. Differently from the master oscillator MO, the amplifier PA does not include the high reflective mirror 76 and the output coupling mirror 77. The pulse laser light incident on the window 71a of the amplifier PA once passes through a laser gain space between the electrode 72a and the electrode 72b and is output from the window 71b. The pulse laser light output from the master oscillator MO is amplified by the amplifier PA and incident on the OPS device 141.

The master oscillator MO and the amplifier PA each include a window 71e provided in the laser chamber 71 and a discharge sensor 81. The window 71e outputs discharge light in the laser chamber 71 toward the discharge sensor 81. Each discharge sensor 81 receives the discharge light to detect that discharge has occurred in the laser chamber 71 and transmits a detection signal to the laser controller 66.

5.2 Operation

Upon receipt of a light emission trigger signal from the anneal device 4, the laser controller 66 controls timing at which the switch 74a in each of the master oscillator MO and the amplifier PA is turned on so that the pulse laser light output from the master oscillator MO is amplified by the amplifier PA. The laser controller 66 detects the discharge timing of the laser chamber 71 in each of the master oscillator MO and the amplifier PA based on the detection signal from each discharge sensor 81.

In this case, the time difference between the discharge timing of the master oscillator MO and the discharge timing of the amplifier PA is defined as a discharge timing delay time DSDT. The laser controller 66 controls the timing at which the switch 74a of each of the master oscillator MO and the amplifier PA is turned on such that the discharge timing delay time DSDT measured by the discharge sensor 81 approaches a predetermined value.

As a result, in synchronization with transmission of the pulse laser light output from the master oscillator MO between the electrode 72a and the electrode 72b in the amplifier PA, discharge is produced to excite a laser gas and amplify the pulse laser light in the amplifier PA. The amplified pulse laser light is output from the amplifier PA and incident on the OPS device 141. The pulse time width of the pulse laser light is stretched in the OPS device 141.

5.3 Example of XeF Excimer Laser, MOPA System, and One-Stage OPS Device

5.3.1 Configuration

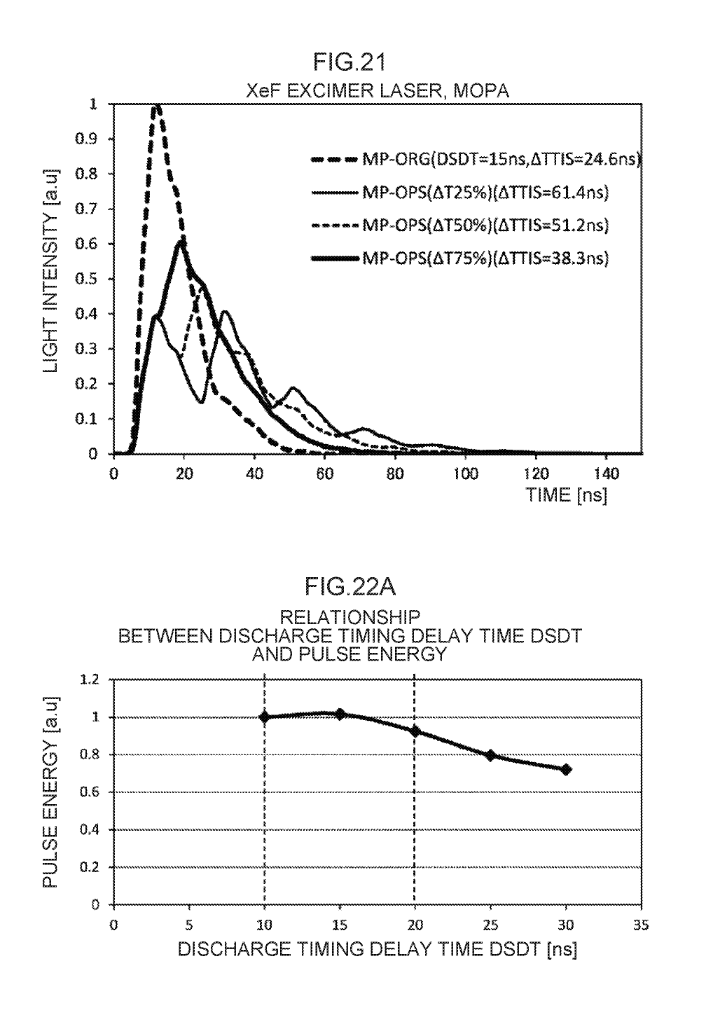

FIG. 21 illustrates an example of the XeF excimer laser using XeF as the laser medium in the laser device 3C of the MOPA system. In the present example, the OPS device 141 is a one-stage OPS device configured by only the first OPS 41A1.

5.3.2 Action

In the laser device 3C, an input waveform MP-ORG of the pulse laser light incident on the OPS device 141 is an output waveform of the pulse laser light amplified by the amplifier PA. As described later, in the MOPA system, the TIS pulse time width ΔT_{TIS} fluctuates in accordance with fluctuation of the discharge timing delay time DSDT. The present example shows an output waveform MP-OPS calculated based on the input waveform MP-ORG in the case of the discharge timing delay time DSDT being 15 ns. In the input waveform MP-ORG of the present example, the TIS pulse time width ΔT_{TIS} is 24.6 ns.

An output waveform MP-OPS indicated by a thin solid line in FIG. 21 is an output waveform in a case where the delay optical path length L(1) corresponding to the pulse full-width ΔT_{25%} of the input waveform MP-ORG is ΔT_{25%}×c. In the input waveform MP-ORG, the pulse full-width ΔT_{25%} is 19.8 ns, and hence the delay optical path length L(1) is set as follows: L(1)=ΔT_{25%}×c=19.8 ns×0.3 m/ns=5.94 m. In the calculation process for L(1), a third decimal point is rounded.

An output waveform MP-OPS indicated by a thin broken line in FIG. 21 is an output waveform in a case where the delay optical path length L(1) corresponding to the pulse full-width ΔT_{50%} of the input waveform MP-ORG is ΔT_{50%}×c. In the input waveform MP-ORG, the pulse full-width ΔT_{50%} is 13.7 ns, and hence the delay optical path length L(1) is set as follows: L(1)=ΔT_{50%}×c=13.7 ns×0.3 m/ns=4.11 m.

An output waveform MP-OPS indicated by a thick solid line in FIG. 21 is an output waveform in a case where the delay optical path length L(1) corresponding to the pulse full-width ΔT_{75%} of the input waveform MP-ORG is ΔT_{75%}×c. In the input waveform MP-ORG, the pulse full-width ΔT_{75%} is 8 ns, and hence the delay optical path length L(1) is set as follows: L(1)=ΔT_{75%}×c=8 ns×0.3 m/ns=2.40 m.

5.3.3 Effect

In FIG. 21, the TIS pulse time width ΔT_{TIS} is 24.6 ns in the input waveform MP-ORG, ΔT_{TIS} is 61.4 ns in the output waveform MP-OPS of ΔT_{25%}, ΔT_{TIS} is 51.2 ns in the output waveform MP-OPS of ΔT_{50%}, and ΔT_{TIS} is 38.3 ns in the output waveform MP-OPS of ΔT_{75%}. Meanwhile, in FIG. 21, in the output waveform MP-OPS of ΔT_{25%}, the decrease in light intensity between the first and second peaks is the maximum among the output waveform MP-OPS. Also in this output waveform MP-OPS of ΔT_{25%}, the decrease in light intensity between the peaks has been suppressed as compared to the comparative example illustrated in FIG. 4. The light intensity ratio Imr of the output waveform MP-OPS of ΔT_{25%} is about 38% or higher, and the light intensity ratio Imr has been improved as compared to the comparative example illustrated in FIG. 4.

As described above, also in the example of the XeF excimer laser of the MOPA system, by setting the delay optical path length L(1) of the first OPS 41A1 in the range of: ΔT_{75%}×c≤L(1)≤ΔT_{25%}×c (the above expression (3)), it is possible to stretch the pulse time width while improving the light intensity ratio Imr. As a result, re-solidification of the amorphous silicon under irradiation with pulse laser light can be prevented, and the melted state of the amorphous silicon can thus be held for a long time. This makes it possible to increase the grain size of crystal of the polycrystalline silicon.

Further, since the amplifier PA is included in the MOPA system, the pulse laser light is amplified to make pulse energy of the pulse laser light high as compared to a case where only the master oscillator MO is included. In the laser annealing, it is possible to further prevent re-solidification of amorphous silicon melted during irradiation with pulse laser light by an amount corresponding to an increase in pulse energy of the pulse laser light. This enables further improvement in effect of increasing the grain size of crystal of the polycrystalline silicon.

5.4 Relationship Between Discharge Timing Delay Time DSDT and Pulse Energy/TIS Pulse Time Width ΔT_{TIS}

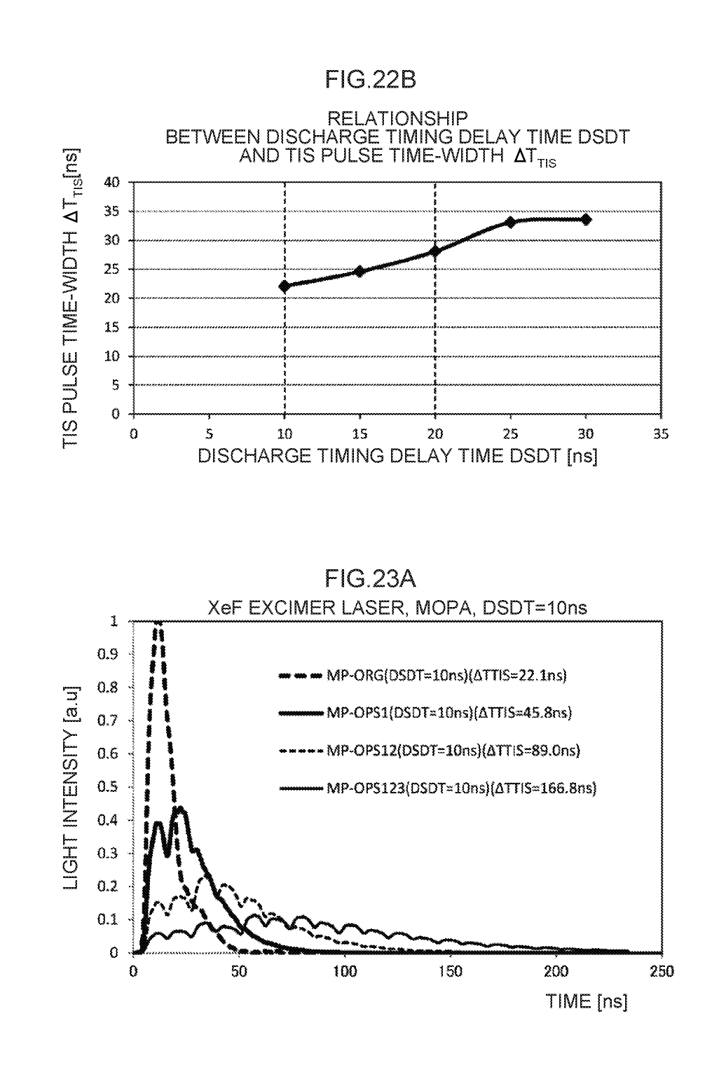

A graph of FIG. 22A represents the relationship between the discharge timing delay time DSDT and the pulse energy in the laser device 3C of the MOPA system. A graph of FIG. 22B illustrates the relationship between the discharge timing delay time DSDT and the TIS pulse time width ΔT_{TIS} in the laser device 3C of the MOPA system. The TIS pulse time width ΔT_{TIS} is the TB pulse time width ΔT_{TIS} of the output waveform of the pulse laser light amplified by the amplifier PA after being output from the master oscillator MO.

As illustrated in FIG. 22A, the discharge timing delay time DSDT at which the pulse energy becomes maximal is 15 ns, and a range of the discharge timing delay time DSDT in which the fluctuation of pulse energy is allowable is from 10 ns to 20 ns. Meanwhile, as illustrated in FIG. 22B, when the discharge timing delay time DSDT is in the range of 10 ns to 20 ns, the TIS pulse time width ΔT_{TIS} of the output waveform of the pulse laser light amplified by the amplifier PA can fluctuate in a range of 22.1 ns to 28.1 ns.

5.5 Suppressing Fluctuation of Pulse Time Width by Combination of MOPA System and OPS Device

5.5.1 Output Waveform in Combination of MOPA System and OPS Device

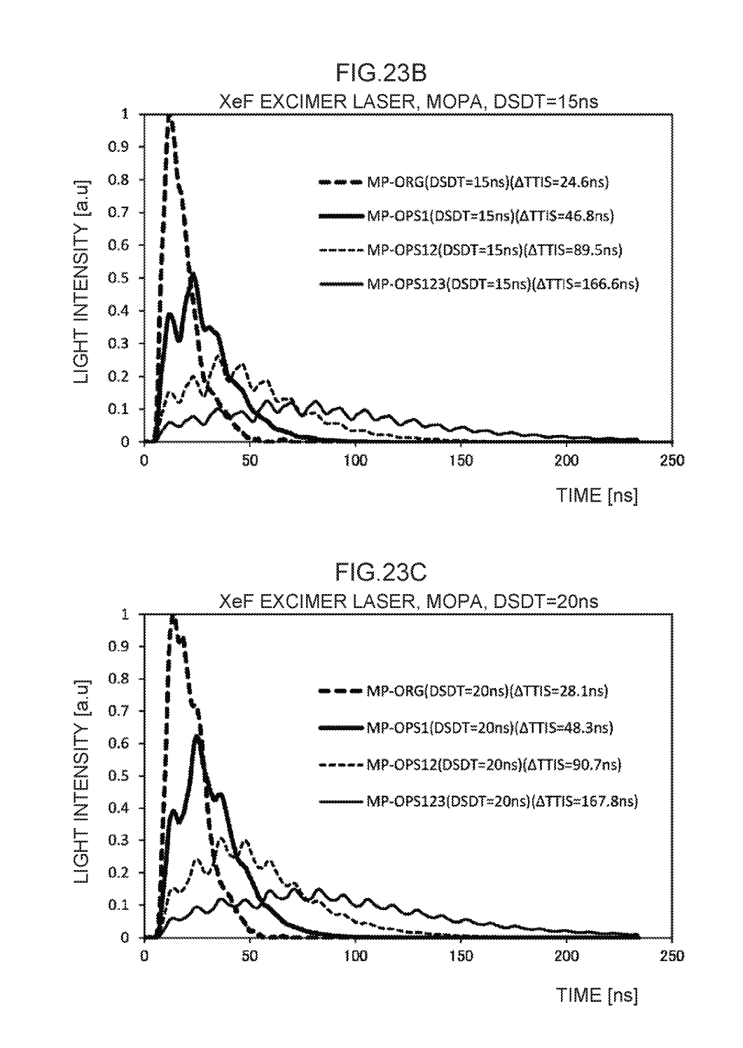

FIGS. 23A to 23C illustrate changes in output waveform from the OPS device 141 when the discharge timing delay time DSDT fluctuates in the laser device 3C of the MOPA system. The present example is an example of an XeF excimer laser using XeF as the laser medium.

FIG. 23A illustrates an output waveform MP-OPS calculated based on the input waveform MP-ORG in the case of the discharge timing delay time DSDT being 10 ns. In the input waveform MP-ORG in the case of DSDT being 10 ns, the TIS pulse time width ΔT_{TIS} is 22.1 ns.

In FIG. 23A, conditions and measurement results of an output waveform MP-OPS1 indicated by a thick solid line are as follows:

(1) number of OPS stages=1

(2) delay optical path length L(1)=3.5 m

(3) TIS pulse time width ΔT_{TIS}=45.8 ns,

where in the case of DSDT being 10 ns, the pulse full-width ΔT₂₅% of the input waveform MP-ORG is 16.4 ns, the pulse full-width ΔT_{50%} is 12 ns, the pulse full-width ΔT_{75%} is 7.6 ns. ΔT_{25%}×c=4.92 m, and ΔT_{75%}×c=2.28 m. Therefore, the set value 3.5 m of the delay optical path length L(1) satisfies the condition represented by: ΔT_{75%}×c≤L(1)≤ΔT_{25%}×c.

In FIG. 23A, conditions and measurement results of an output waveform MP-OPS12 indicated by a thin broken line are as follows:

(1) number of OPS stages=2

(2) delay optical path length L(1)=3.5 m
delay optical path length L(2)=2×L(1)=2×3.5 m=7 m

(3) TIS pulse time width ΔT_{TIS}=89.0 ns.

In FIG. 23A, conditions and measurement results of an output waveform MP-OPS123 indicated by a thin solid line are as follows:

(1) number of OPS stages=3

(2) delay optical path length L(1)=3.5 m
delay optical path length L(2)=2×L(1)=2×3.5 m=7 m
   delay optical path length L(3)=2×L(2)=2×7 m=14 m

(3) TIS pulse time width ΔT_{TIS}=166.8 ns.

FIG. 23B illustrates an output waveform MP-OPS calculated based on the input waveform MP-ORG in the case of the discharge timing delay time DSDT being 15 ns. In the input waveform MP-ORG in the case of DSDT being 15 ns, the TIS pulse time width ΔT_{TIS} is 24.6 ns.

In FIG. 23B, conditions and measurement results of an output waveform MP-OPS1 indicated by a thick solid line are as follows:

(1) number of OPS stages=1

(2) delay optical path length L(1)=3.5 m

(3) TIS pulse time width ΔT_{TIS}=46.8 ns,

where in the case of DSDT being 15 ns, the pulse full-width ΔT_{25%} of the input waveform MP-ORG is 19.8 ns, the pulse full-width ΔT_{50%} is 13.7 ns, the pulse full-width ΔT_{75%} is 8 ns, and ΔT_{25%}×c=19.8 ns×0.3 m/ns=5.94 m, and ΔT_{75%}×c=8 ns×0.3 m/ns=2.40 m. Therefore, the set value 3.5 m of the delay optical path length L(1) satisfies the condition represented by: ΔT_{75%}×c≤L(1)≤ΔT_{25%}×c.

In FIG. 23B, conditions and measurement results of an output waveform MP-OPS12 indicated by a thin broken line are as follows:

(1) number of OPS stages=2

(2) delay optical path length L(1)=3.5 m
delay optical path length L(2)=2×L(1)=2×3.5 m=7 m

(3) TIS pulse time width ΔT_{TIS}=89.5 ns.

In FIG. 23B, conditions and measurement results of an output waveform MP-OPS123 indicated by a thin solid line are as follows:

(1) number of OPS stages=3

(2) delay optical path length L(1)=3.5 m
delay optical path length L(2)=2×L(1)=2×3.5 m=7 m
delay optical path length L(3)=2×L(2)=2×7 m=14 m

(3) TIS pulse time width ΔT_{TIS}=166.6 ns.

FIG. 23C illustrates an output waveform MP-OPS calculated based on the input waveform MP-ORG in the case of the discharge timing delay time DSDT being 20 ns. In the input waveform MP-ORG in the case of DSDT being 20 ns, the TIS pulse time width ΔT_{TIS} is 28.1 ns.

In FIG. 23C, conditions and measurement results of an output waveform MP-OPS1 indicated by a thick solid line are as follows:

(1) number of OPS stages=1

(2) delay optical path length L(1)=3.5 m

(3) TIS pulse time width ΔT_{TIS}=48.3 ns,

where in the case of DSDT being 20 ns, the pulse full-width ΔT_{25%} of the input waveform MP-ORG is 24.4 ns, the pulse full-width ΔT_{50%} is 18.4 ns, the pulse full-width ΔT_{75%} is 10.8 ns, ΔT_{25%}×c=7.32 mn, and ΔT_{75%}×c=3.24 m. Therefore, the set value 3.5 m of the delay optical path length L(1) satisfies the condition represented by: ΔT_{75%}×c≤L(1)≤ΔT_{25%}×c.

In FIG. 23C, conditions and measurement results of an output waveform MP-OPS12 indicated by a thin broken line are as follows:

(1) number of OPS stages=2

(2) delay optical path length L(1)=3.5 m
delay optical path length L(2)=2×L(1)=2×3.5 m=7 m

(3) TIS pulse time width ΔT_{TIS}=90.7 ns.

In FIG. 23C, conditions and measurement results of an output waveform MP-OPS123 indicated by a thin solid line are as follows:

(1) number of OPS stages=3

(2) delay optical path length L(1)=3.5 m
delay optical path length L(2)=2×L(1)=2×3.5 m=7 m
delay optical path length L(3)=2×L(2)=2×7 m=14 m

(3) TIS pulse time width ΔT_{TIS}=167.8 ns.

5.5.2 Effect to Suppress Fluctuation of TIS Pulse Time Width ΔT_{TIS}

As illustrated in FIG. 22B, in the case of the MOPA system, when the discharge timing delay time DSDT fluctuates between 10 ns and 20 ns, the TIS pulse time width ΔT_{TIS} of the output waveform of the pulse laser light output from the amplifier PA fluctuates in the range of 22.1 ns to 28.1 ns. The output waveform of the pulse laser light output from the amplifier PA corresponds to the input waveform MP-ORG to be input into the OPS device 141 in FIGS. 23A to 23C. That is, in the input waveform IMP-ORG before being incident on the OPS device 141, the TIS pulse time width ΔT_{TIS} also fluctuates in a range of about 6 ns in accordance with the fluctuation of the discharge timing delay time DSDT.

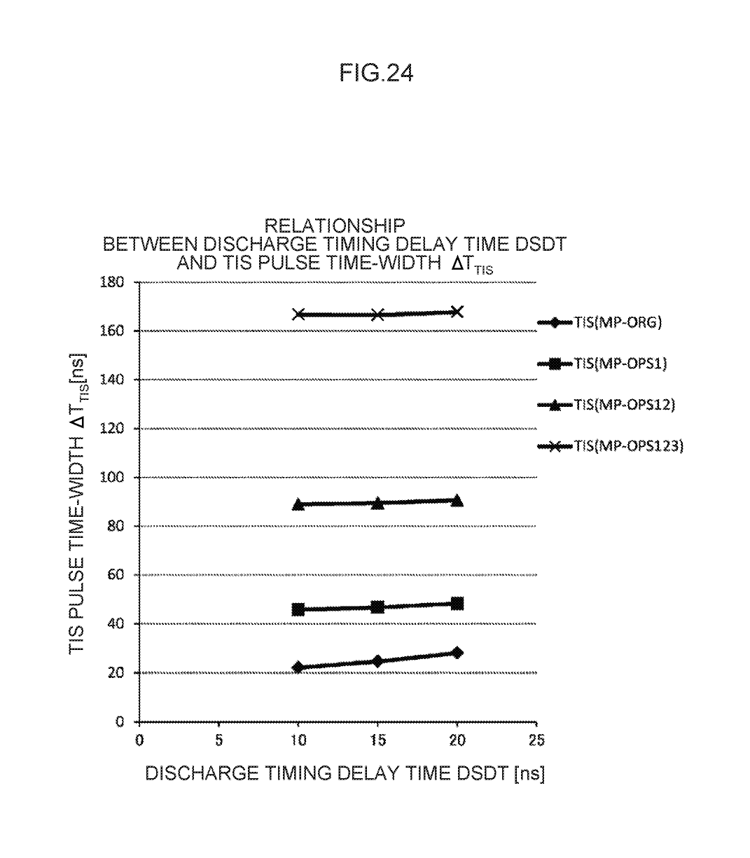

FIG. 24 illustrates the relationship between the discharge timing delay time DSDT and the TIS pulse time width ΔT_{TIS} in the case of using each of a one-stage OPS device, a two-stage OPS device, and a three-stage OPS device based on the TIS pulse time width ΔT_{TIS} of each output waveform MP-OPS in FIGS. 23A to 23C. In FIG. 24, the graph TIS of the MP-ORG plotted by rhombic marks represents fluctuation of the TIS pulse time width ΔT_{TIS} of the input waveform MP-ORG in the range of 22.1 ns to 28.1 ns.

In FIG. 24, the graph TIS of the MP-OPS1 represents fluctuation of the TIS pulse time width ΔT_{TIS} in the case of using the one-stage OPS device. In the case of using the one-stage OPS device, the TIS pulse time width ΔT_{TIS} fluctuates in a range of 45.8 ns to 48.3 ns. However the fluctuation width of the TIS pulse time width ΔT_{TIS} is about 2.5 ns, and the fluctuation of the TIS pulse time width ΔT_{TIS} due to the fluctuation of the discharge timing delay time DSDT is suppressed, as compared to the graph TIS of MP-ORG with the fluctuation width of about 6 ns.

In FIG. 24, the graph TIS of the MP-OPS12 represents fluctuation of the TIS pulse time width ΔT_{TIS} in the case of using the two-stage OPS device. In the case of using the two-stage OPS device, the TIS pulse time width ΔT_{TIS} fluctuates in a range of 89.0 ns to 90.7 ns. However, the fluctuation width of the TIS pulse time width ΔT_{TIS} is about 1.7 ns, and the fluctuation of the TIS pulse time width ΔT_{TIS} due to the fluctuation of the discharge timing delay time DSDT is suppressed, as compared to the graph TIS of MP-ORG with the fluctuation width of about 6 ns.

In FIG. 24, the graph TIS of the MP-OPS123 represents fluctuation of the TIS pulse time width ΔT_{TIS} in the case of using the three-stage OPS device. In the case of using the three-stage OPS device, the TIS pulse time width ΔT_{TIS} fluctuates in a range of 166.8 ns to 167.8 ns. However, the fluctuation width of the TIS pulse time width ΔT_{TIS} is about 1 ns, and the fluctuation of the TIS pulse time width ΔT_{TIS} due to the fluctuation of the discharge timing delay time DSDT is suppressed, as compared to the graph TIS of MP-ORG with the fluctuation width of about 6 ns.

As described above, the fluctuation of the TIS pulse time width ΔT_{TIS} due to the fluctuation of the discharge timing delay time DSDT is suppressed, and even when the discharge timing delay time DSDT fluctuates in the MOPA system, it is possible to suppress the fluctuation of the grain size of crystal of the polycrystalline silicon.

5.5.3 Others

In the all output waveforms MP-OPS in FIGS. 23A to 23C, the light intensity ratio Imr is 50% or higher. Thus, also in the present example where the MOPA system and the OPS device are combined, it is possible to stretch the pulse time width while improving the light intensity ratio Imr. As a result, the effect of increasing the grain size of the polycrystalline silicon can also be expected.

### 6. Preferable Ranges of Various Conditions

6.1 More Preferable Range of Delay Optical Path Length L(1)

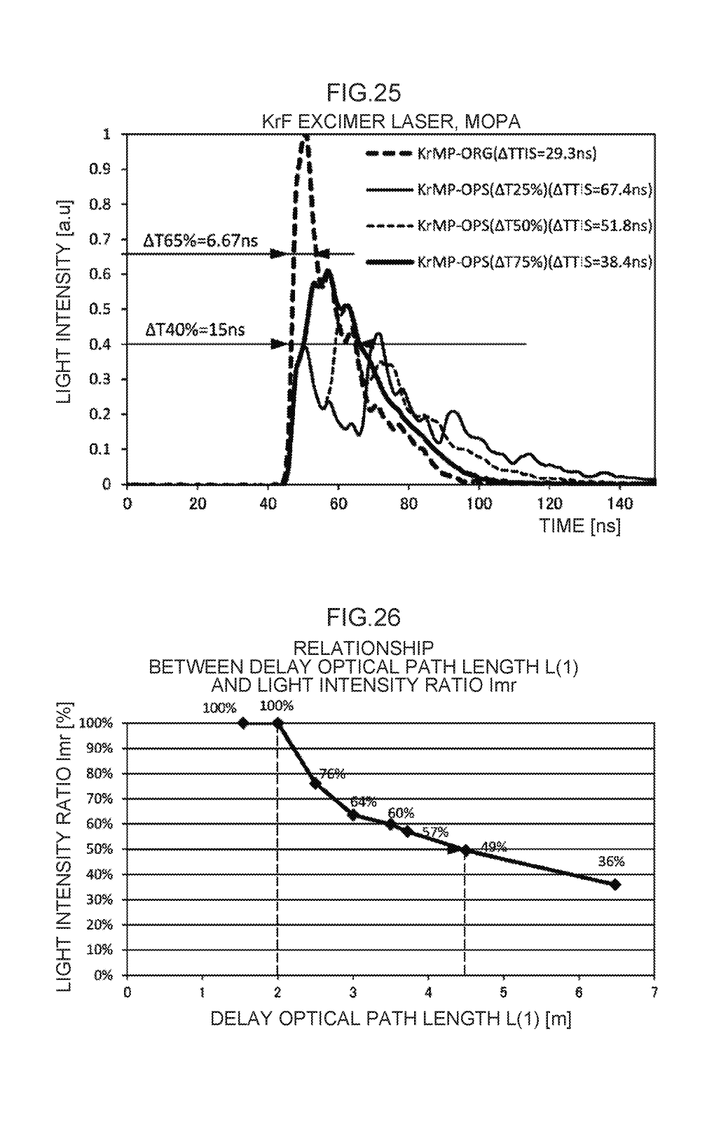

FIG. 25 illustrates an example of the KrF excimer laser of the MOPA system using KrF as the laser medium of the laser device 3C illustrated in the third embodiment. FIG. 25 illustrates an output waveform KrMP-OPS calculated based on an input waveform KrMP-ORG. The delay optical path length L(1) of the first OPS is set in the range of: ΔT_{75%}×c≤L(1)≤ΔT_{25%}×c (expression (3)).

In FIG. 25, conditions of the input waveform KrMP-ORG are as follows:

(1) discharge timing delay time DSDT=20 ns

(2) TIS pulse time width ΔT_{TIS}=29.3 ns

(3) pulse full-width ΔT_{25%}=21.6 ns,
pulse full-width ΔT_{50%}=12.4 ns,
and pulse full-width ΔT_{75%}=5.2 ns.

In FIG. 25, calculation conditions and measurement results of the output waveform KrMP-OPS in the case of ΔT_{25%} are as follows:

(1) number of OPS stages=1

(2) delay optical path length L(1)=ΔT_{25%}×c=21.6 ns×0.3 m/ns=6.48 m

(3) TIS pulse time width ΔT_{TIS}=67.4 ns.

In FIG. 25, calculation conditions and measurement results of the output waveform KrMP-OPS in the case of ΔT_{50%} are as follows:

(1) number of OPS stages=1

(2) delay optical path length L(1)=ΔT_{75%}×c=12.4 ns×0.3 m/ns=3.72 m

(3) TIS pulse time width ΔT_{TIS}=51.8 ns.

In FIG. 25, calculation conditions and measurement results of the output waveform KrMP-OPS in the case of ΔT_{75%} are as follows:

(1) number of OPS stages=1

(2) delay optical path length L(1) ΔT_{75%}×c=5.2 ns×0.3 m/ns=1.56 m

(3) TIS pulse time width ΔT_{TIS}=38.4 ns.

In all the output waveforms KrMP-OPS illustrated in FIG. 25, the light intensity ratio Imr is about 36% or higher. The TIS pulse time width ΔT_{TIS} is 38.4 ns in the output waveform KrMP-OPS of ΔT_{75%}, Iris is 51.8 ns in the output waveform KrMP-OPS of ΔT_{50%}, and ΔT_{TIS} is 67.4 ns in the output waveform KrMP-OPS of ΔT₂₅%. Each output waveform KrMP-OPS has a long pulse time width with respect to 29.3 ns of the input waveform KrMP-ORG. In this manner, it is possible to stretch the pulse time width while improving the light intensity ratio Imr. An effect can thus be expected in which, during irradiation with the pulse laser light, re-solidification of the amorphous silicon in the melted state is prevented to increase the grain size of the polycrystalline silicon.

FIG. 26 is a graph representing the relationship between the delay optical path length L(1) and a light intensity ratio Imr. The graph illustrated in FIG. 26 is obtained by plotting the light intensity ratio Imr of the output waveform KrMP-OPS in accordance with each delay optical path length L(1) in the case of changing the delay optical path length L(1) corresponding to the pulse full-width of the input waveform KrMP-ORG illustrated in FIG. 25.

In the graph illustrated in FIG. 26, the range of the delay optical path length L(1) with the light intensity ratio Imr being equal to or higher than 50% and lower than 100% is represented by: 2 m<L(1)≤4.5 m, When the delay optical path length L(1) is in this range, it is possible to stretch the TIS pulse time width ΔT_{TIS} while ensuring the light intensity ratio Imr of 50% or higher.

As illustrated in FIG. 3, in the OPS, each circulation light PS is sequentially output while being delayed by the delay time DT corresponding to the delay optical path length L. As described above, the relationship between the delay optical path length L and the delay time DT is represented by: DT=L/c. Then, the range of the delay time DT in accordance with the range of: 2 m<L(1)≤4.5 m, is represented by: 2 m/c<DT≤4.5 m/c and 6.67 ns<DT≤15 ns.

When this range is converted into the pulse full-width of the input waveform KrMP-ORG illustrated in FIG. 25 to calculate the range of the delay optical path length L, the following expression (5) is obtained:

ΔT_{65%}×c≤L(1)≤ΔT_{40%}×c (5).

When the delay optical path length L(1) is in a range satisfying the condition represented by the expression (5), it is possible to stretch the pulse time width while holding the light intensity ratio at 50% or higher. Therefore, the delay optical path length L(1) is further preferably in a range satisfying the condition represented by the expression (5), in addition to being in the range of satisfying the above expression (3).

6.2 Preferable Range of Reflectance RB of Beam Splitter

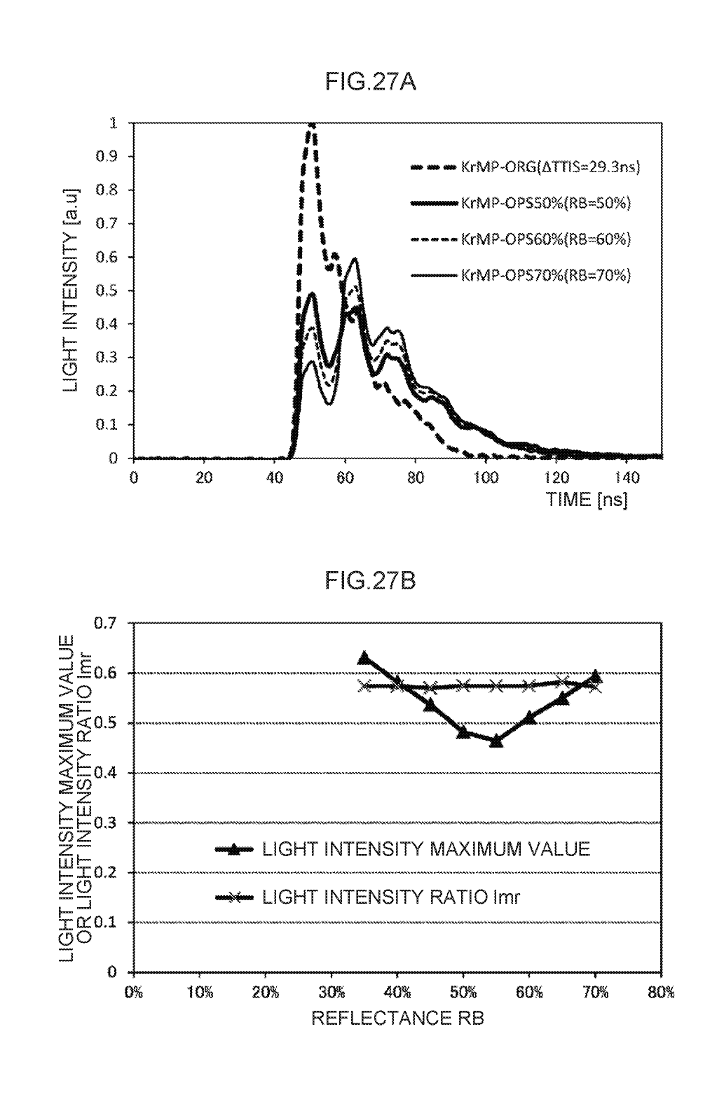

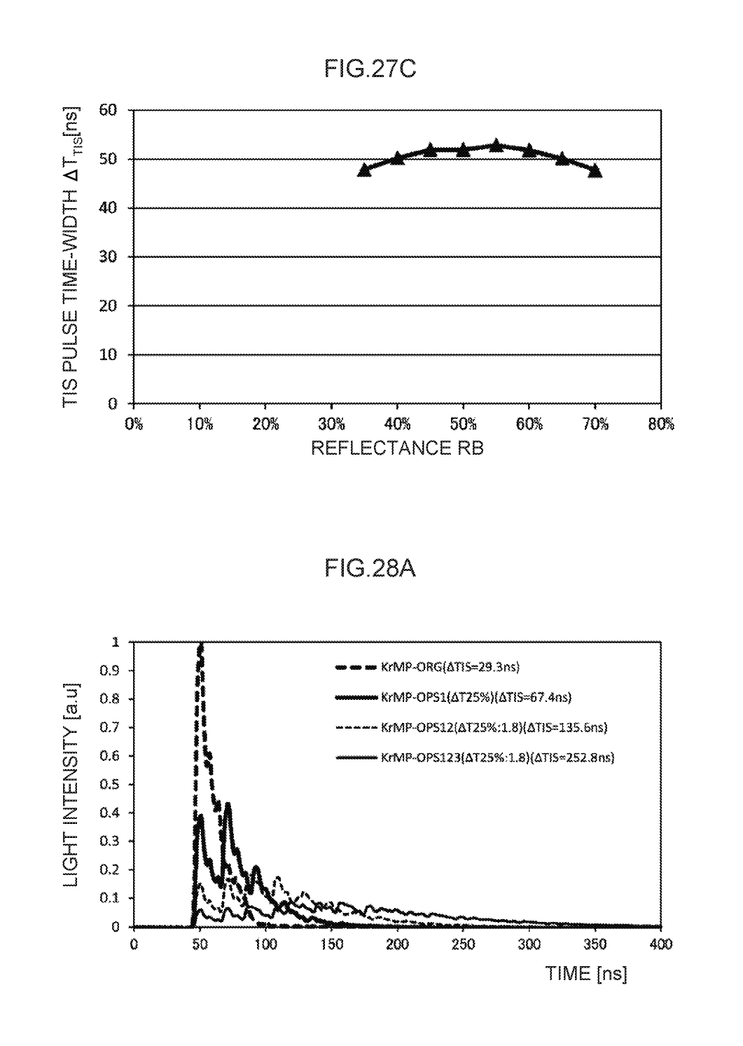

A graph illustrated in FIG. 27A represents a change in output waveform KrMP-OPS in the case of changing the reflectance of the beam splitter, by taking the KrF excimer laser of the MOPA system as an example. An input waveform KrMP-ORG illustrated in FIG. 27A is a waveform based on data measured with actual equipment in accordance with the KrF excimer laser. The input waveform KrMP-ORG is an input waveform in the case of the discharge timing delay time DSDT being 20 ns, and the TIS pulse time width ΔT_{TIS} is 29.3 ns.

The output waveform KrMP-OPS is a waveform calculated based on the input waveform KrMP-ORG. Calculation conditions and measurement results of each output waveform KrMP-OPS are as follows:

(1) number of OPS stages=1

(2) delay optical path length L(1)=pulse full-width of the input waveform KrMP-ORG: ΔT_{50%}×C=12.4 ns×0.3 m/ns=3.72 m

(3) the reflectance RB of the beam splitter

the reflectance RB of the output waveform KrMP-OPS 50%: RB=50%,

the reflectance RB of the output waveform KrMP-OPS 60%: RB=60%,

the reflectance RB of the output waveform KrMP-OPS 70%: RB=70%.

FIG. 27B is a graph representing the relationship between the reflectance RB and the maximum value of the light intensity, and the relationship between the reflectance RB and the light intensity ratio, calculated based on the output waveform KrMP-OPS of FIG. 27A. FIG. 27C is a graph representing the relationship between the reflectance RB and the TIS pulse time width ΔT_{TIS}, calculated based on the output waveform KrMP-OPS of FIG. 27A.

As illustrated in FIG. 27A, in each output waveform KrMP-OPS, the higher the reflectance RB becomes, the more the first peak value of the output waveform KrMP-OPS decreases and, on the contrary, the more the second peak value increases. The higher the reflectance RB becomes, the more the light intensity decreases in the valley between the first and second peaks.

As illustrated in FIG. 27B, the graph representing a change in maximum value of the light intensity of each output waveform KrMP-OPS in accordance with the change of the reflectance RB becomes a curve projecting downward, and the reflectance RB of 55% is the minimum value. As illustrated in FIGS. 27A and 27B, when the reflectance RB is lower than 55%, the first peak becomes the maximum value, and when the reflectance RB is higher than 55%, the second peak becomes the maximum value.

On the other hand, as illustrated in FIG. 27B, in the output waveform KrMP-OPS, the light intensity ratio Imr hardly changes while the reflectance RB changes in the range of the reflectance RB from 30% to 70%. Further, as illustrated in FIG. 27C, a graph representing the relationship between the TIS pulse time width ΔT_{TIS} and the reflectance RB becomes a curve projecting upward, and the reflectance RB at which the TIS pulse time width ΔT_{TIS} becomes maximal is about 55%.

In the range of the reflectance RB from 40% to 65%, the TIS pulse time width ΔT_{TIS} becomes 50 ns or longer. In the range of the reflectance from 40% to 65%, the light intensity ratio Imr is held at about 57% or higher, as illustrated in FIG. 27B. The maximum value of the output waveform KrMP-OPS also shifts around 0.5. As illustrated in FIG. 27C, the TIS pulse time width ΔT_{TIS} is held at 55 ns or longer and does not change greatly.

Hence, the reflectance RB of the beam splitter 42 is preferably in the range of the following expression (6):

40%≤RB≤65% (6).

6.3 Preferable Range of Delay Optical Path Length L(1)

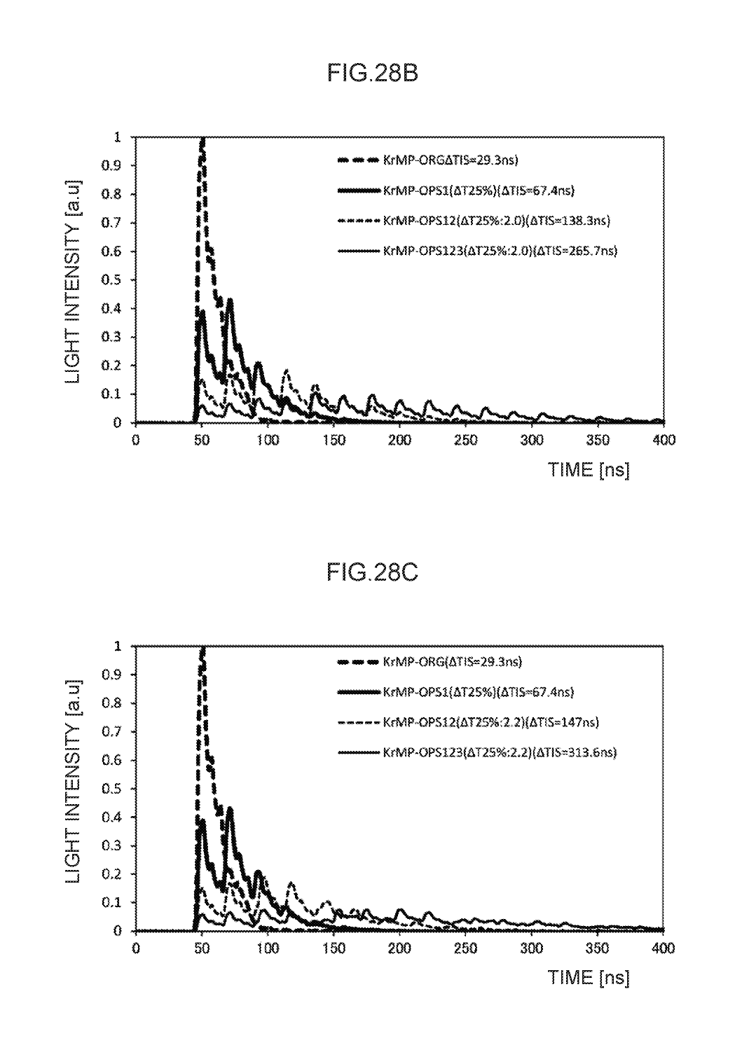

FIGS. 28A to 30C each illustrate the output waveform KrMP-OPS in the case of changing the delay optical path length L and the number of stages of the OPS device, taking the KrF excimer laser of the MOPA system as an example. The input waveform KrMP-ORG illustrated in each of FIGS. 28A to 30C is an input waveform in the case of the discharge timing delay time DSDT being 20 ns, and the TIS pulse time width ΔT_{TIS} is 29.3 ns, similarly to the input waveform KrMP-ORG shown in FIG. 27A.

Each of FIGS. 28A to 28C is the output waveform KrMP-OPS in the case of setting the delay optical path length L(1) of the first OPS 41A1 to the pulse full-width ΔT_{25%}×c. In FIGS. 28A to 28C, a coefficient by which a delay optical path length L(k−1) is multiplied is changed, the delay optical path length L(k−1) being a reference at the time of setting the delay optical path lengths L(2), L(3) of the second and third OPSs 41A2, 41A3. The coefficient of FIG. 28A is 1.8, the coefficient of FIG. 28B is 2.0, and the coefficient of FIG. 28C is 2.2.

Calculation conditions and measurement results of each output waveform KrMP-OPS of ΔT_{25%} in FIG. 28A are as follows:

A1: output waveform KrMP-OPS1 of ΔT₂₅%

(1) number of OPS stages=1

(2) delay optical path length L(1)=ΔT_{25%}×c=21.6 ns×0.3 m/ns=6.48 m

(3) TIS pulse time width ΔT_{TIS}=67.4 ns

A2: output waveform KrMP-OPS12 of ΔT_{25%}, coefficient=1.8

(1) number of OPS stages=2

(2) delay optical path length L(1)=ΔT_{25%}×c=6.48 m
delay optical path length L(2)=1.8×L(1)=1.8×6.48 m=11.66 m

(3) TIS pulse time width ΔT_{TIS}=135.6 ns

A3: output waveform KrMP-OPS123 of ΔT_{25%}, coefficient=1.8

(1) number of OPS stages=3

(2) delay optical path length L(1)=ΔT_{25%}×c=6.48 m
delay optical path length L(2)=1.8×L(1)=11.66 m
delay optical path length L(3)=1.8×L(2)=1.8×11.66 m=21 m

(3) TIS pulse time width ΔT_{TIS}=252.8 ns.

Calculation conditions and measurement results of each output waveform KrMP-OPS of ΔT_{25%} in FIG. 28B are as follows:

B1: output waveform KrMP-OPS1 of ΔT_{25%}

(1) number of OPS stages=1

(2) delay optical path length L(1)=ΔT_{25%}×c=6.48 m

(3) TIS pulse time width ΔT_{TIS}=67.4 ns

B2: output waveform KrMP-OPS12 of ΔT_{25%}), coefficient=2.0

(1) number of OPS stages=2

(2) delay optical path length L(1)=ΔT_{25%}×c=6.48 m
delay optical path length L(2)=2.0×L(1)=2.0×6.48 m=12.96 m

(3) TIS pulse time width ΔT_{TIS}=138.3 ns

B3: output waveform KrMP-OPS123 of ΔT_{25%}, coefficient=2.0

(1) number of OPS stages=3

(2) delay optical path length L(1)=ΔT_{25%}×c=6.48 m
delay optical path length L(2)=2.0×L(1)=12.96 m
delay optical path length L(3)=2.0×L(2)=2.0×12.96 m=25.92 m

(3) TIS pulse time width ΔT_{TIS}=265.7 ns.

Calculation conditions and measurement results of each output waveform KrMP-OPS of ΔT_{25%} in FIG. 28C are as follows:

C1: output waveform KrMP-OPS1 of ΔT_{25%}

(1) number of OPS stages=1

(2) delay optical path length L(1)=ΔT_{25%}×c=6.48 m

(3) TIS pulse time width ΔT_{TIS}=67.4 ns

C2: output waveform KrMP-OPS12 of ΔT_{25%}, coefficient=2.2

(1) number of OPS stages=2

(2) delay optical path length L(1)=ΔT_{25%}×c=6.48 m
delay optical path length L(2)=2×L(1)=2.2×6.48 m=14.26 m

(3) TIS pulse time width ΔT_{TIS}=147 ns

C3: output waveform KrMP-OPS123 of ΔT_{25%}, coefficient=2.2

(1) number of OPS stages=3

(2) delay optical path length L(1) ΔT_{25%}×c=6.48 m
delay optical path length L(2)=2.2×L(1)=14.26 m
delay optical path length L(3)=2.2×L(2)=2.2×14.26 m=31.37 m

(3) TIS pulse time width ΔT_{TIS}=313.6 ns.

As long as the delay optical path lengths L(1), L(2), L(3) are in the ranges illustrated in FIGS. 28A to 28C, by using any of the one-stage to three-stage OPS devices, the decrease in light intensity can be suppressed to hold the light intensity ratio Imr at a relatively high value. In the examples of FIGS. 28A to 28C, when the three-stage OPS device is used in conditions of: L(1), L(2)=1.8×L(1), and L(3)=1.8×L(2), the TIS pulse time width ΔT_{TIS} can be stretched to 252.8 ns. Further, in conditions of: L(1), L(2)=2.2×L(1), and L(3)=2.2×L(2), when the three-stage OPS device is used, the TIS pulse time width ΔT_{TIS} is can be stretched to 313.6 ns.

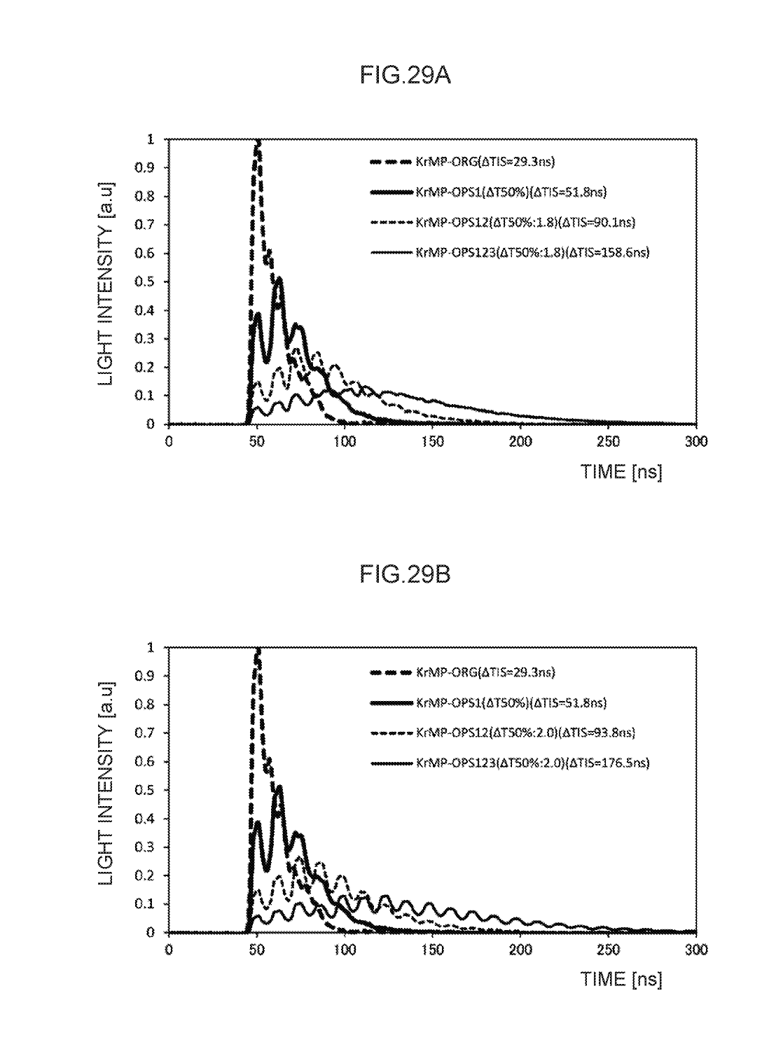

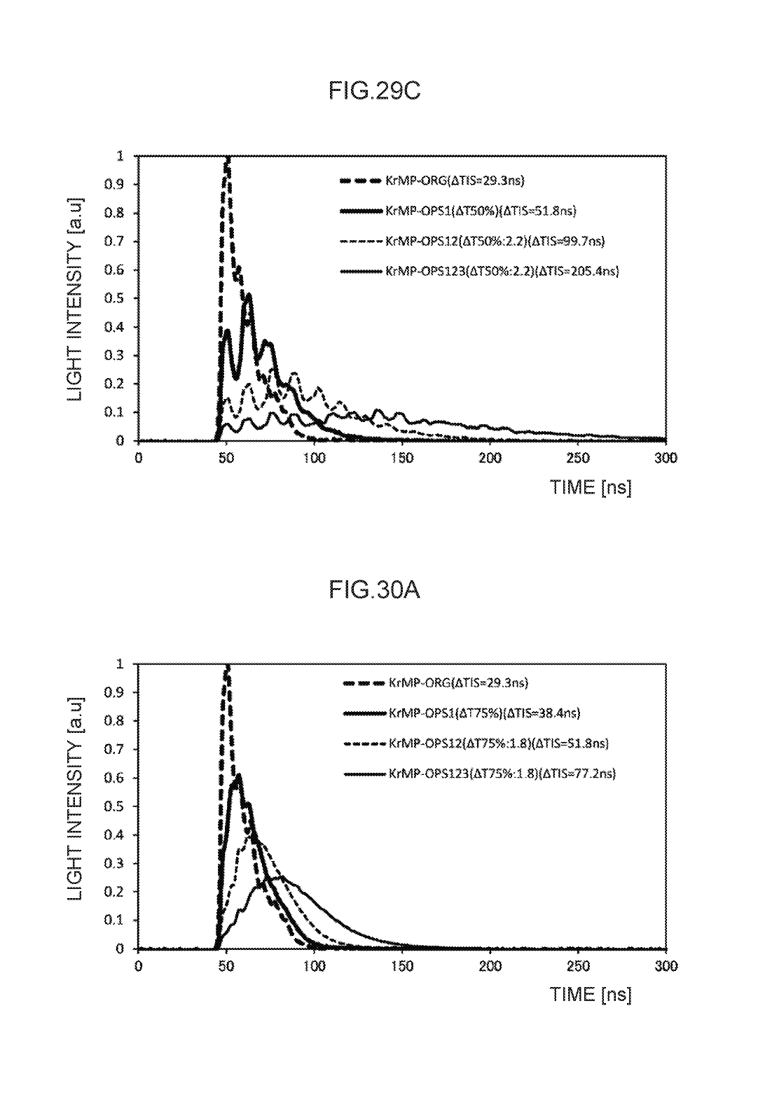

Each of FIGS. 29A to 29C is the output waveform KrMP-OPS in the case of setting the delay optical path length L(1) of the first OPS 41A1 to the pulse full-width ΔT_{50%}×c. Similarly to FIGS. 28A and 28C, the coefficient of FIG. 29A is 1.8, the coefficient of FIG. 29B is 2.0, and the coefficient of FIG. 29C is 2.2.

Calculation conditions and measurement results of each output waveform KrMP-OPS of ΔT_{50%} in FIG. 29A are as follows:

A1: output waveform KrMP-OPS1 of ΔT_{50%}

(1) number of OPS stages=1

(2) delay optical path length L(1)=ΔT_{50%}×c=12.4 ns×0.3 m/ns=3.72 m

(3) TIS pulse time width ΔT_{TIS}=51.8 ns

A2: output waveform KrMP-OPS12 of ΔT_{50%}, coefficient=1.8

(1) number of OPS stages=2

(2) delay optical path length L(1)=ΔT_{50%}×c=3.72 m
delay optical path length L(2)=1.8×L(1)=1.8×3.72 m=6.7 m

(3) TIS pulse time width ΔT_{TIS}=90.1 ns

A3: output waveform KrMP-OPS123 of ΔT_{50%}, coefficient=1.8

(1) number of OPS stages=3

(2) delay optical path length L(1)=ΔT_{50%}×c=3.72 m
delay optical path length L(2)=1.8×L(1)=6.7 m
delay optical path length L(3)=1.8×L(2)=1.8×6.7 m=12 m

(3) TIS pulse time width ΔT_{TIS}=158.6 ns.

Calculation conditions and measurement results of each output waveform KrMP-OPS of ΔT_{50%} in FIG. 29B are as follows:

B1: output waveform KrMP-OPS1 of ΔT_{50%}

(1) number of OPS stages=1

(2) delay optical path length L(1)=ΔT_{50%}×c=3.72 m

(3) TIS pulse time width ΔT_{TIS}=51.8 ns

B2: output waveform KrMP-OPS12 of ΔT_{50%}, coefficient=2.0

(1) number of OPS stages=2

(2) delay optical path length L(1)=ΔT_{50%}×c=3.72 m
delay optical path length L(2)=2.0×L(1)=2.0×3.72 m=7.44 m

(3) TIS pulse time width ΔT_{TIS}=93.8 ns

B3: output waveform KrMP-OPS123 of ΔT_{50%}, coefficient=2.0

(1) number of OPS stages=3

(2) delay optical path length L(1)=ΔT_{50%}×c=3.72 m
delay optical path length L(2)=2.0×L(1)=7.44 m
delay optical path length L(3)=2.0×L(2)=2.0×7.44 m=14.88 m

(3) TIS pulse time width ΔT_{TIS}=176.5 ns.

Calculation conditions and measurement results of each output waveform KrMP-OPS of ΔT_{50%} in FIG. 29C are as follows:

C1: output waveform KrMP-OPS1 of ΔT_{50%}

(1) number of OPS stages=1

(2) delay optical path length L(1)=ΔT_{50%}×c=3.72 m

(3) TIS pulse time width ΔT_{TIS}=51.8 ns

C2: output waveform KrMP-OPS12 of ΔT_{50%}, coefficient=2.2

(1) number of OPS stages=2

(2) delay optical path length L(1)=ΔT_{50%}×c=3.72 m
delay optical path length L(2)=2.2×L(1)=2.2×3.72 m=8.18 m

(3) TIS pulse time width ΔT_{TIS}=99.7 ns

C3: output waveform KrMP-OPS123 of ΔT_{50%}, coefficient=2.2

(1) number of OPS stages=3

(2) delay optical path length L(1) ΔT_{50%}×c=3.72 m
delay optical path length L(2)=2.2×L(1)=8.18 m
delay optical path length L(3)=2.2×L(2)=2.2×8.18=18 m

(3) TIS pulse time width ΔT_{TIS}=205.4 ns.

As long as the delay optical path lengths L(1), L(2), L(3) are in the ranges illustrated in FIGS. 29A to 29C, by using any of the one-stage to three-stage OPS devices, the decrease in light intensity can be suppressed to hold the light intensity ratio Imr at a relatively high value. In the examples of FIGS. 29A to 29C, when the three-stage OPS device is used in conditions of: L(1), L(2)=1.8×L(1), and L(3)=1.8×L(2), the TIS pulse time width ΔT_{TIS} can be stretched to 158.6 ns. Further, in conditions of: L(1), L(2)=2.2×L(1), and L(3) 2.24(2), when the three-stage OPS device is used, the TIS pulse time width ΔT_{TIS} can he stretched to 205.4 ns.

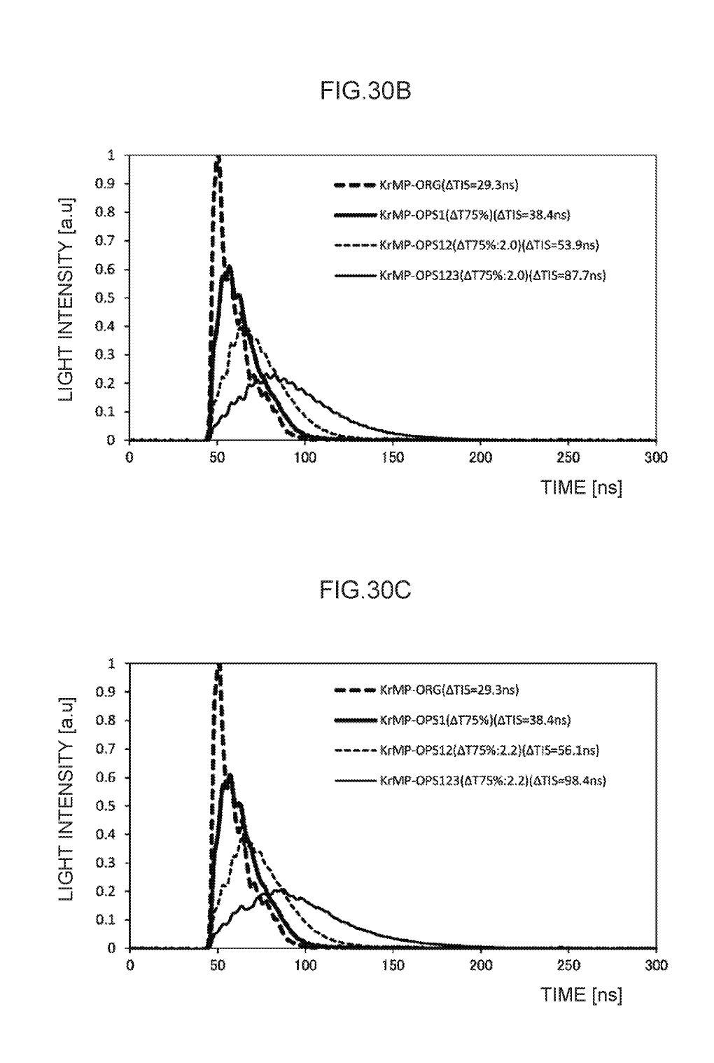

Each of FIGS. 30A to 30C is the output waveform KrMP-OPS in the case of setting the delay optical path length L(1) of the first OPS 41A1 to the pulse full-width ΔT_{75%}×c. Similarly to FIGS. 28A and 28C, the coefficient of the graph in FIG. 30A is 1.8, the coefficient of FIG. 30B is 2.0, and the coefficient of FIG. 30C is 2.2.

Calculation conditions and measurement results of each output waveform KrMP-OPS of ΔT_{75%} in FIG. 30A are as follows:

A1: output waveform KrMP-OPS1 of ΔT_{75%}

(1) number of OPS stages=1

(2) delay optical path length L(1)=ΔT_{75%}×c=5.13 ns×0.3 m/ns=1.54 m

(3) TIS pulse time width ΔT_{TIS}=38.4 ns

A2: output waveform KrMP-OPS12 of ΔT_{75%}, coefficient=1.8

(1) number of OPS stages=2

(2) delay optical path length L(1)=ΔT_{75%}×c=1.54 m
delay optical path length L(2)=1.8×L(1)=1.8×1.54 m =2.77 m

(3) TIS pulse time width ΔT_{TIS}=51.8 ns

A3: output waveform KrMP-OPS 123 of ΔT_{75%}, coefficient=1.8

(1) number of OPS stages=3

(2) delay optical path length L(1)=ΔT_{75%}×c=1.54 m
delay optical path length L(2)=1.8×L(1)=2.77 m
delay optical path length L(3)=1.8×L(2)=1.8×2.77 m=4.99 m

(3) TIS pulse time width ΔT_{TIS}=77.2 ns.

Calculation conditions and measurement results of each output waveform KrMP-OPS of ΔT_{75%} in FIG. 30B are as follows:

B1: output waveform KrMP-OPS1 of ΔT_{75%}

(1) number of OPS stages=1

(2) delay optical path length L(1)=ΔT_{75%}×c=1.54 m

(3) TIS pulse time width ΔT_{TIS}=38.4 ns

B2: output waveform KrMP-OPS12 of ΔT_{75%}, coefficient=2.0

(1) number of OPS stages=2

(2) delay optical path length L(1)=ΔT_{50%}×c=1.54 m
delay optical path length L(2)=2.0×L(1)=2.0×1.54 m=3.08 m

(3) TIS pulse time width ΔT_{TIS}=53.9 ns

B3: output waveform KrMP-OPS123 of ΔT_{75%}, coefficient=2.0

(1) number of OPS stages=3

(2) delay optical path length L(1)=ΔT_{75%}×c=1.54 m
delay optical path length L(2)=2.0×L(1)=3.08 m
delay optical path length L(3)=2.0×L(2)=2.0×3.08 m=6.16 m

(3) TIS pulse time width ΔT_{TIS}=87.7 ns

Calculation conditions and measurement results of each output waveform KrMP-OPS of ΔT_{75%} in FIG. 30C are as follows:

C1: output waveform KrMP-OPS1 of ΔT_{75%}

(1) number of OPS stages=1

(2) delay optical path length L(1)=ΔT_{75%}×c=1.54 m

(3) TIS pulse time width ΔT_{TIS}=38.4 ns

C2: output waveform KrMP-OPS12 of ΔT_{75%}, coefficient=2.2

(1) number of OPS stages=2

(2) delay optical path length L(1)=ΔT_{75%}×c=1.54 m
delay optical path length L(2)=2.2×L(1)=2.2×1.54 m=3.39 m

(3) TIS pulse time width ΔT_{TIS}=56.1 ns

C3: output waveform KrMP-OPS123 of ΔT_{75%}, coefficient=2.2

(1) number of OPS stages=3

(2) delay optical path length L(1)=ΔT_{75%}×c=1.54 m
delay optical path length L(2)=2.2×L(1)=3.39 m
delay optical path length L(3)=2.2×L(2)=2.2×3.39=7.45 m

(3) TIS pulse time width ΔT_{TIS}=98.4 ns.

As long as the delay optical path lengths L(1), L(2), L(3) are in the ranges illustrated in FIGS. 30A to 30C, by using any of the one-stage to three-stage OPS devices, the decrease in light intensity can be suppressed to hold the light intensity ratio Imr at a relatively high value. In the examples of FIGS. 30A to 30C, when the three-stage OPS device is used in conditions of: L(1), L(2)=1.8×L(1), and L(3)=1.8×L(2), the TIS pulse time width ΔT_{TIS} can be stretched to 77.2 ns. Further, in conditions of: L(1), L(2)=2.2×L(1), and L(3)=2.2×L(2), when the three-stage OPS device is used, the TIS pulse time width ΔT_{TIS} can be stretched to 98.4 ns.

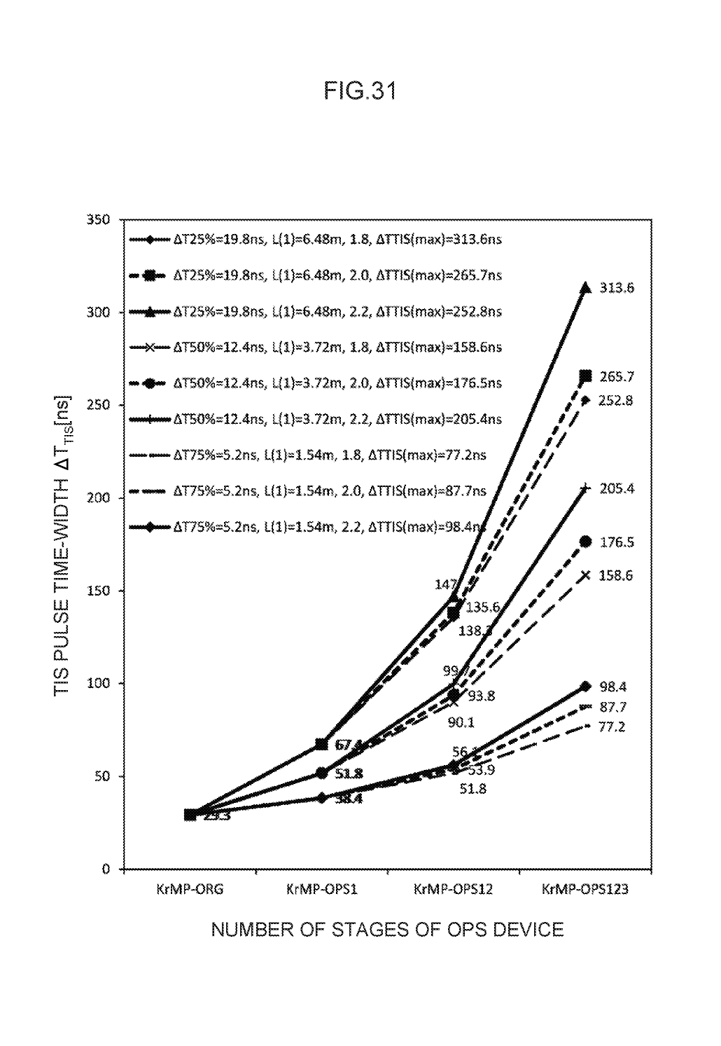

FIG. 31 is a graph representing the relationship between each aspect of the OPS devices being the examples illustrated in FIGS. 28A to 30C and the TIS pulse time width ΔT_{TIS}. In this case, each aspect of the OPS device is the number of stages of the OPS device, the delay optical path length L, or the like. When the delay optical path length L(1) is set in the range of: ΔT_{75%}×c≤L(1)≤ΔT_{25%}×c, in the one-stage OPS device represented by the graph KrMP-OPS1, the TIS pulse time width ΔT_{TIS} is stretched in the range of 38.4 ns to 67.4 ns. Similarly, in the two-stage OPS device represented by the graph KrMP-OPS12, the TIS pulse time width ΔT_{TIS} is stretched in the range of 51.8 ns to 147 ns. Similarly, in the three-stage OPS device represented by the graph KrMP-OPS123, the TIS pulse time width ΔT_{TIS} is stretched in the range of 77.2 ns to 313.6 ns.

As long as the delay optical path lengths L(1), L(2), L(3) are in the ranges illustrated in FIGS. 29A to 31, it is possible to suppress the decrease in light intensity and to stretch the TIS pulse time width ΔT_{TIS} while holding a relatively high light intensity ratio Imr. Conditions of the delay optical path lengths L(1), L(2), L(3) illustrated in FIGS. 29A to 31 are shown by the following expression (7).

When the OPS device includes the second to n-th OPSs arranged sequentially, in addition to the first OPS, the delay optical path length L(k) of the k-th OPS satisfies the following expression (7):

1.8×L(k−1)≤L(k)≤2.2×L(k−1) (7),

where k is from 2 to n, both inclusive.

By setting the delay optical path length L as in the expression (7), it is possible to suppress the decrease in light intensity and to stretch the TIS pulse time width ΔT_{TIS} while holding a relatively high light intensity ratio Imr. However, as illustrated in above expression (4), it is more preferable to set the delay optical path length L so as to satisfy the condition represented by: L(k)=2×L(k−1). This is because, by defining the delay optical path length L(k) by an integer multiple of the delay optical path length L which becomes a reference, advantages can be expected in designing, the easiness to obtain a concave mirror, and the like.

6.4 Others

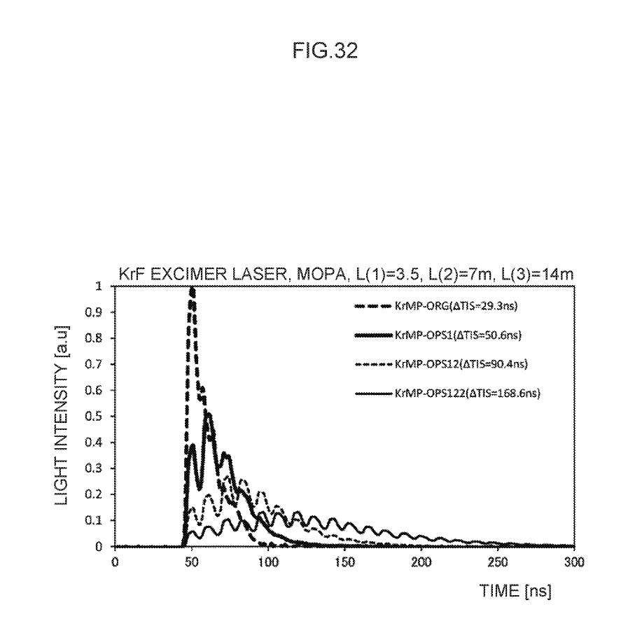

FIG. 32 is an example of the KrF excimer laser of the MOPA system in which the delay optical path lengths L(1), L(2), L(3) have been set so as to satisfy the condition represented by the expression (4). KrMP-ORG is a waveform in the case of the discharge timing delay time DSDT being 15 ns.

In the input waveform KrMP-ORG, since ΔT_{75%} is 5.2 ns and ΔT_{25%} is 19.8 ns, ΔT_{75%}×c is 1.54 m and ΔT_{25%}×c is 6.48 m. Therefore, the set value L(1) being 3.5 m satisfies the condition represented by: ΔT_{75%}×c≤L(1)≤ΔT_{25%}×c (expression (3)).

L(2) and L(3) are set as follows: L(2)=2×L(1)=2×3.5 m=7 m and L(3)=2×L(2)=2×7 m=14 m, and satisfy the condition represented by: L(k)=2×L(k−1), in the expression (4).

As illustrated in FIG. 32, in any of the output waveform KrMP-ORG1 by use of the one-stage OPS device, the output waveform KrMP-ORG12 by use of the two-stage OPS device, and the output waveform KrMP-ORG123 by use of the three-stage OPS device, the decrease in light intensity between the first and second peaks has been suppressed as compared to the comparative example illustrated in FIG. 4. The light intensity ratio Imr is 50% or higher. When the three-stage OPS device is used, as represented in the output waveform KrMP-ORG123, it is possible to stretch the TIS pulse time width ΔT_{TIS} from 29.3 ns of the input waveform KrMP-ORG to 168.6 ns. Hence it is possible to stretch the TIS pulse time width ΔT_{TIS} while holding a relatively high light intensity ratio Imr.

The above description is intended not to give limitations but to show simple examples. Hence it would be obvious for a skilled person in the field to be able to make a change in each embodiment of the present disclosure without deviating from the scope of the accompanying claims.

The terms used in the whole of the present specification and the accompanying claims should be interpreted as “non-restrictive” terms. For example, the terms “include” or “included” should be interpreted as “not limited to those described as being included.” The term “have” should be interpreted as “not limited to those described as having.” Further, the modifier “one” described in the present specification and the accompanying claims should be interpreted as meaning “one”, “at least on”, or “one or more than one.”

What is claimed is:

1. A laser device for use in laser annealing, comprising:
(1) a laser oscillator configured to output pulse laser light; and
(2) an optical pulse stretcher (OPS) device disposed on an optical path of the pulse laser light output from the laser oscillator and including a first OPS configured to stretch a pulse time width of the pulse laser light incident on the first OPS, by transmitting a part of the pulse laser light and causing the other part of the pulse laser light to circulate through a delay optical path and to be output,
a delay optical path length L(1) as a length of the delay optical path of the first OPS being in a range of the following expression (A),
ΔT_{75%}×c≤L(1)=ΔT_{25%}×c (A),
where ΔT_{a %} is a time full-width of a position at which light intensity represents a value of a % with respect to a peak value in an input waveform of the pulse laser light that is output from the laser oscillator and incident on the OPS device, and c is light speed.

2. The laser device according to claim 1, wherein
the delay optical path length L(1) of the first OPS is in a range of the following expression (B),
ΔT_{65%}×c≤L(1)≤ΔT_{40%}×c (B).

3. The laser device according to claim 1, wherein
the OPS device includes second to n-th OPSs arranged in series with the first OPS, in addition to the first OPS, and
a delay optical path L(k) of a k-th OPS satisfies a condition shown in the following expression (C),
1.8×L(k−1)≤L(k)≤2.2×L(k−1) (C),
where k is from 2 to n, both inclusive.

4. The laser device according to claim 3, wherein
the delay optical path length L(k) satisfies a condition shown in the following expression (D),
L(k)=2×L(k−1) (D).

5. The laser device according to claim 1, wherein
the first OPS includes a beam splitter configured to transmit a part of the pulse laser light and reflect the other part of the pulse laser light toward the delay optical path, and
a reflectance of the beam splitter is within a range of 40% to 65%, both inclusive.

6. The laser device according to claim 3, wherein
the first to nth OPSs are arranged in ascending order of the delay optical path length from the laser oscillator side.

7. The laser device according to claim 1, further comprising
(3) an amplifier disposed on an optical path between the laser oscillator and the OPS device.

8. The laser device according to claim 7, wherein
the delay optical path length L(1) of the first OPS is in a range of the following expression (B),
ΔT_{65%}×c≤L(1)≤ΔT_{40%}×c (B).

9. The laser device according to claim 7, wherein
the OPS device includes second to n-th OPSs arranged in series with the first OPS, in addition to the first OPS, and
a delay optical path length L(k) of a k-th OPS satisfies a condition shown in the following expression (C),
1.8×L(k−1)≤L(k)≤2.2×L(k−1) (C),
where k is from 2 to n, both inclusive.

10. The laser device according to claim 9, wherein
the delay optical path length L(k) satisfies a condition shown in the following expression (D).
L(k)=2×L(k−1) (D).

11. The laser device according to claim 7, wherein
the first OPS includes a beam splitter configured to transmit a part of the pulse laser light and reflect the other part of the pulse laser light toward the delay optical path, and
a reflectance of the beam splitter is within a range of 40% to 65%, both inclusive.

12. The laser device according to claim 9, wherein
the first to n-th OPSs are arranged in ascending order of the delay optical path length L from the laser oscillator side.

13. A laser anneal device comprising:
(1) a laser device including a laser oscillator configured to output pulse laser light;
(2) an optical pulse stretcher (OPS) device disposed on an optical path of the pulse laser light output from the laser oscillator and including a first OPS configured to stretch a pulse time width of the pulse laser light incident on the first OPS, by transmitting a part of the pulse laser light and causing the other part of the pulse laser light to circulate through a delay optical path and to be output, and in Which a delay optical path length L(1) as a length of the delay optical path of the first OPS being in a range of the following expression (A); and
(3) an anneal device configured to anneal a semiconductor thin film by using the pulse laser light stretched by the OPS device,
ΔT_{75%}×c≤L(1)≤ΔT_{25%}×c (A),
where ΔT_{a %} is a time full-width of a position at which light intensity represents a value of a % with respect to a peak value in an input waveform of the pulse laser light that is output from the laser oscillator and incident on the OPS device, and c is light speed.

14. The laser anneal device according to claim 13, wherein
the delay optical path length L(1) of the first OPS is in a range of the following expression (B),
ΔT_{65%}×c≤L(1)≤ΔT_{40%}×c (B).

15. The laser anneal device according to claim 13, wherein
the OPS device includes second to n-th OPSs arranged in series with the first OPS, in addition to the first OPS, and
a delay optical path length L(k) of a k-th OPS satisfies a condition shown in the following expression (C),
1.8×L(k−1)≤L(k)≤2.2×L(k−1) (C),
where k is from 2 to n, both inclusive.

16. The laser anneal device according to claim 15, wherein
the delay optical path length L(k) satisfies a condition shown in the following expression (D),
L(k)=2×L(k−1) (D).

17. The laser anneal device according to claim 13, wherein
the first OPS includes a beam splitter configured to transmit a part of the pulse laser light and reflect the other part of the pulse laser light toward the delay optical path, and
a reflectance of the beam splitter is within a range of 40% to 65%, both inclusive.

18. The laser anneal device according to claim 15, wherein
the first to n-th OPSs are arranged in ascending order of the delay optical path length from the laser oscillator side.

19. The laser anneal device according to claim 13, further comprising
(4) an amplifier disposed on an optical path between the laser oscillator and the OPS device.
